(19) United States
(12) Patent Application Publication
(10) Pub. No.: US 2012/0064665 A1
(43) Pub. Date: Mar. 15, 2012

(54) DEPOSITION APPARATUS, APPARATUS FOR SUCCESSIVE DEPOSITION, AND METHOD FOR MANUFACTURING SEMICONDUCTOR DEVICE

(75) Inventor: Shunpei YAMAZAKI, Setagaya (JP)

(73) Assignee: SEMICONDUCTOR ENERGY LABORATORY CO., LTD., Atsugi (JP)

(21) Appl. No.: 13/225,613

(22) Filed: Sep. 6, 2011

(30) Foreign Application Priority Data
Sep. 13, 2010 (JP) 2010-204909

(51) Int. Cl. H01L 21/36; C23C 16/40

(52) U.S. Cl. 438/104; 118/724; 257/E21.461

(57) ABSTRACT

An oxide semiconductor layer is formed with a deposition apparatus including a transfer mechanism for a substrate, a first deposition chamber in which an oxide semiconductor is deposited, and a first heating chamber in which first heat treatment is performed. The first deposition chamber and the first heating chamber are sequentially provided along a path of the substrate transferred by the transfer mechanism. The substrate is held so that an angle formed by a deposition surface of the substrate and the vertical direction is in a range of greater than or equal to 1° and less than or equal to 30°. Without exposure to the air, the first heat treatment can be performed after a first film is formed over the substrate.

### BACKGROUND OF THE INVENTION

1. Field of the Invention

The present invention relates to a deposition apparatus and an apparatus for successive deposition. The present invention relates to a method for manufacturing a semiconductor device.

Note that a semiconductor device in this specification and the like refers to all devices which can function by utilizing semiconductor characteristics, and electro-optical devices, semiconductor circuits, and electronic devices are all semiconductor devices.

2. Description of the Related Art

In recent years, a technique by which a thin film transistor (also referred to as a TFT) is manufactured using a semiconductor thin film (having a thickness of approximately several tens of nanometers to several hundreds of nanometers) formed over a substrate having an insulating surface has attracted attention. Thin film transistors are applied to a wide range of electronic devices such as ICs or electro-optical devices, and prompt development of thin film transistors that are to be used as switching elements in image display devices, in particular, is being pushed.

There are various kinds of metal oxides, which are used for a variety of applications, and some metal oxides have semiconductor characteristics. Examples of such a metal oxide having semiconductor characteristics include tungsten oxide, tin oxide, indium oxide, zinc oxide, indium-gallium-zinc-based oxide, and the like. Thin film transistors in which a channel formation region is formed using such a metal oxide having semiconductor characteristics are already known (Patent Documents 1 and 2).

Meanwhile, there is a trend in an active matrix semiconductor device typified by a liquid crystal display device towards a larger screen, e.g., a 60-inch diagonal screen, and further, development of an active matrix semiconductor device is aimed even at a screen size of a diagonal of 120 inches or more. In addition, a trend in resolution of a screen is toward higher definition, e.g., high-definition (HD) image quality (1366×768) or full high-definition (FHD) image quality (1920×1080), and prompt development of a so-called 4K Digital Cinema display device, which has a resolution of 3840×2048 or 4096×2180, is also pushed.

Such an increase in the size of a semiconductor device leads to an increase in the size of a glass substrate for production of a liquid crystal panel, for example, from a size of 300 mm×400 mm called the first generation to a size of 550 mm×650 mm of the third generation, 730 mm×920 mm of the fourth generation, 1000 mm×1200 mm of the fifth generation, 1450 mm×1850 mm of the sixth generation, 1870 mm×2200 mm of the seventh generation, 2000 mm×2400 mm of the eighth generation, 2400 mm×2800 mm of the ninth generation, or 2880 mm×3080 mm of the tenth generation. The size of a glass substrate is expected to be further increased to the size of the eleventh generation or the twelfth generation in the future.

### REFERENCE

### [Patent Document]

[Patent Document 1] Japanese Published Patent Application No. 2007-123861
[Patent Document 2] Japanese Published Patent Application No. 2007-96055

### SUMMARY OF THE INVENTION

When hydrogen or water, which forms an electron donor, is included in an oxide semiconductor in a manufacturing process of a device, the electrical conductivity of the oxide semiconductor might be changed. Such a phenomenon becomes a factor of variation in electric characteristics of a transistor including the oxide semiconductor. Further, electric characteristics of a semiconductor device including the oxide semiconductor are changed by irradiation with visible light or ultraviolet light.

Further, along with the above increase in the size of a substrate, the size of a deposition apparatus has been increased. However, a deposition apparatus having a large floor area (so-called footprint) causes a problem of high cost in designing of a clean room as well as limitation on the layout of the clean room.

The present invention is made in view of the foregoing technical background. An object of one embodiment of the present invention is to provide a deposition apparatus with which a semiconductor device having stable electric characteristics and high reliability is realized. Another object is to provide a deposition apparatus which enables mass production of highly reliable semiconductor devices with the use of a large-sized substrate such as a mother glass. Another object is to provide a method for manufacturing a semiconductor device having stable electric characteristics and high reliability with the use of the deposition apparatus.

One embodiment of the present invention is a deposition apparatus including a transfer mechanism for a substrate, a first deposition chamber in which a first film including an oxide is formed, and a first heating chamber in which first heat treatment is performed. The first deposition chamber and the first heating chamber are sequentially provided along a path of the substrate transferred by the transfer mechanism. The substrate is held so that an angle formed by a deposition surface of the substrate and the vertical direction is in a range of greater than or equal to 1° and less than or equal to 30°. Without exposure to the air, the first heat treatment is performed after the first film is formed over the substrate.

One embodiment of the present invention is a deposition apparatus in which the first film includes an oxide semiconductor.

One embodiment of the present invention is a deposition method including the steps of forming a first film including an oxide over a substrate in a first deposition chamber, and then performing first heat treatment in a first heating chamber without exposure to the air. The substrate is processed while being held so that an angle formed by a deposition surface of the substrate and the vertical direction is in a range of greater than or equal to 1° and less than or equal to 30°.

One embodiment of the present invention is a deposition method in which the first film includes an oxide semiconductor.

The deposition apparatus of one embodiment of the present invention includes the first deposition chamber in which an oxide semiconductor is deposited, and the first heating chamber connected thereto.

The oxide semiconductor deposited in the first deposition chamber preferably includes at least indium (In) or zinc (Zn). In particular, In and Zn are preferably included. As a stabilizer for reducing variation in electric characteristics of a transistor using the oxide semiconductor, gallium (Ga) is preferably additionally included. Tin (Sn) is preferably included as a stabilizer. Hafnium (Hf) is preferably included as a stabilizer. Aluminum (Al) is preferably included as a stabilizer.

As another stabilizer, one or plural kinds of lanthanoid such as lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), or lutetium (Lu) may be included.

As the oxide semiconductor, for example, indium oxide, tin oxide, zinc oxide, a two-component metal oxide such as an In—Zn-based oxide, a Sn—Zn-based oxide, an Al—Zn-based oxide, a Zn—Mg-based oxide, a Sn—Mg-based oxide, an In—Mg-based oxide, or an In—Ga-based oxide, a three-component metal oxide such as an In—Ga—Zn-based oxide (also referred to as IGZO), an In—Al—Zn-based oxide, an In—Sn—Zn-based oxide, a Sn—Ga—Zn-based oxide, an Al—Ga—Zn-based oxide, a Sn—Al—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, or an In—Lu—Zn-based oxide, or a four-component metal oxide such as an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, or an In—Hf—Al—Zn-based oxide can be used.

Note that here, for example, an “In—Ga—Zn-based oxide” means an oxide including In, Ga, and Zn as main components and there is no limitation on the ratio of In, Ga, and Zn. The In—Ga—Zn-based oxide may include a metal element other than In, Ga, and Zn.

Alternatively, a material expressed by the chemical formula I nMO₃(ZnO), (m>0) may be used as the oxide semiconductor. Note that M represents one or more metal elements selected from Ga, Fe, Mn, and Co. Alternatively, as the oxide semiconductor, a material expressed by the chemical formula In₃SnO₅(ZnO)ₙ (n>0) may be used.

For example, an In—Ga—Zn-based oxide with an atomic ratio of In:Ga:Zn=1:1:1 (=1/3:1/3:1/3) or In:Ga:Zn=2:2:1 (=2/5:2/5:1/5), or any of oxides whose composition is in the neighborhood of the above compositions can be used. Alternatively, an In—Sn—Zn-based oxide with an atomic ratio of In:Sn:Zn=1:1:1 (=1/3:1/3:1/3), In:Sn:Zn=2:1:3 (=1/3:1/6:1/2), or In:Sn:Zn=2:1:5 (=1/4:1/8:5/8), or any of oxides whose composition is in the neighborhood of the above compositions may be used.

Note that for example, the expression “the composition of an oxide including In, Ga, and Zn at the atomic ratio, In:Ga:Zn=a:b:c (a+b+c=1), is in the neighborhood of the composition of an oxide including In, Ga, and Zn at the atomic ratio, In:Ga:Zn=A:B:C (A+B+C=1)” means that a, b, and c satisfy the following relation: (a−A)²+(b−B)²+(c−C)²≦r², and r may be 0.05, for example. The same applies to other oxides.

In the first heating chamber, the substrate can be heated at a temperature higher than or equal to 200° C. and lower than or equal to 750° C.

The oxide semiconductor deposited in the first deposition chamber is transferred to the first heating chamber without exposure to the air and heat treatment is successively performed, whereby impurities such as hydrogen, water, and a hydroxyl group in an oxide semiconductor film can be removed and an oxide semiconductor film in which impurities are extremely reduced can be obtained. Here, the heat treatment is performed at a temperature higher than or equal to 250° C. and lower than or equal to 750° C., preferably higher than or equal to 400° C. and lower than or equal to 750° C., in an atmosphere of nitrogen, oxygen, a rare gas typified by argon, or a mixed gas of any of these.

In the above deposition apparatus, deposition treatment, heat treatment, and transfer are performed without exposure to the air; thus, the treatment and the transfer can always be performed in a clean atmosphere. Accordingly, the impurity concentration in a film and at an interface of the film can be extremely reduced and a highly reliable oxide semiconductor layer can be formed.

By using an oxide semiconductor layer formed with a deposition apparatus having such a structure for a channel formation region of a transistor, for example, a semiconductor device having stable electric characteristics and high reliability can be realized.

In the first deposition chamber and the first heating chamber, the substrate to be processed is held so that an angle formed by a deposition surface thereof and the vertical direction is at least in a range of greater than or equal to 1° and less than or equal to 30°, preferably greater than or equal to 5° and less than or equal to 15°. With such a structure in which treatment can be performed with the substrate standing, an increase in the floor area (so-called footprint) of the apparatus can be suppressed; accordingly, designing of a clean room is facilitated and cost can be suppressed. Moreover, with a structure in which the substrate can be held while being inclined slightly against the vertical direction, the substrate can be supported even under reduced pressure. Although use of a clamp can be given as a method for supporting the substrate without inclining it, this method has problems in that deposition is not performed on a substrate surface which overlaps with a clamp portion and in that dust is generated from the clamp portion.

Furthermore, the deposition apparatus in which treatment can be performed with the substrate standing at the above angle can have a smaller floor area (so-called footprint), and enables mass production of highly reliable semiconductor devices even with the use of a large-sized substrate such as mother glasses of the fifth to twelfth generations.

A plurality of the above structures in which a deposition chamber and a heating chamber are connected, where treatment can be performed while a substrate is held so that an angle formed by a deposition surface thereof and the vertical direction is at least in a range of greater than or equal to 1° and less than or equal to 30°, preferably greater than or equal to 5° and less than or equal to 15°, is provided along a path of the substrate, whereby a deposition apparatus with which a semiconductor layer having higher reliability can be formed over a large-sized substrate can be obtained.

That is, one embodiment of the present invention is an apparatus for successive deposition including a transfer mechanism for a substrate, a first deposition chamber in which a first film including an insulating film is formed, a first heating chamber in which first heat treatment is performed, a second deposition chamber in which a second film including an oxide is formed, and a second heating chamber in which second heat treatment is performed. The first deposition chamber, the first heating chamber, the second deposition chamber, and the second heating chamber are sequentially provided along a path of the substrate transferred by the transfer mechanism. The substrate is held so that an angle formed by a deposition surface of the substrate and the vertical direction is in a range of greater than or equal to 1° and less than or equal to 30°. Without exposure to the air, the first heat treatment is performed after formation of the first film, and then the second heat treatment is performed after formation of the second film.

One embodiment of the present invention is an apparatus for successive deposition including a transfer mechanism for a substrate, a first deposition chamber in which a first film including an oxide including at least a first metal element and a second metal element is formed, a first heating chamber in which first heat treatment is performed, a second deposition chamber in which a second film including an oxide is formed, and a second heating chamber in which second heat treatment is performed. The first deposition chamber, the first heating chamber, the second deposition chamber, and the second heating chamber are sequentially provided along a path of the substrate transferred by the transfer mechanism. The substrate is held so that an angle formed by a deposition surface of the substrate and the vertical direction is in a range of greater than or equal to 1° and less than or equal to 30°. Without exposure to the air, the first heat treatment is performed after formation of the first film, and then the second heat treatment is performed after formation of the second film.

One embodiment of the present invention is an apparatus for successive deposition in which the second film includes an oxide semiconductor.

One embodiment of the present invention is an apparatus for successive deposition in which the first metal element is zinc.

One embodiment of the present invention is an apparatus for successive deposition in which the second metal element is gallium.

One embodiment of the present invention is a deposition method including the steps of forming a first film including an insulating film over a substrate in a first deposition chamber, performing first heat treatment in a first heating chamber, forming a second film including an oxide in a second deposition chamber, and performing second heat treatment in a second heating chamber. The substrate is processed while being held so that an angle formed by a deposition surface of the substrate and the vertical direction is in a range of greater than or equal to 1° and less than or equal to 30°.

One embodiment of the present invention is a deposition method including the steps of forming a first film including an oxide including at least a first metal element and a second metal element over a substrate in a first deposition chamber, performing first heat treatment in a first heating chamber, forming a second film including an oxide in a second deposition chamber, and performing second heat treatment in a second heating chamber. The substrate is processed while being held so that an angle formed by a deposition surface of the substrate and the vertical direction is in a range of greater than or equal to 1° and less than or equal to 30°.

One embodiment of the present invention is a deposition method in which the second film includes an oxide semiconductor.

One embodiment of the present invention is a deposition method in which the first metal element is zinc.

One embodiment of the present invention is a deposition method in which the second metal element is gallium.

The above first deposition chamber has a sputtering apparatus with which an insulating film or an oxide film including at least a first metal element and a second metal element can be formed. The temperature at which the oxide film is formed in the first deposition chamber may be higher than or equal to 200° C. and lower than or equal to 400° C.

In the case where an insulating film is formed, for example, a film used as a gate insulating film or a base film of a transistor can be formed.

In the above, the first metal element may be zinc. The second metal element may be gallium.

In the first heating chamber, heat treatment can be performed on the substrate over which the oxide film is formed in the first deposition chamber. When the heat treatment is performed at a temperature higher than or equal to 400° C. and lower than or equal to 750° C., a first crystalline oxide semiconductor layer can be obtained. Depending on the temperature of the first heat treatment, the first heat treatment causes crystallization from a film surface and crystal grows from the film surface toward the inside of the film; thus, c-axis aligned crystal is obtained. By the first heat treatment, large amounts of zinc and oxygen gather to the film surface, and one or more layers of graphene-type two-dimensional crystal including zinc and oxygen and having a hexagonal upper plane (a schematic plan view thereof is shown in FIG. 7A) are formed at the outermost surface; the layer(s) at the outermost surface grow in the thickness direction to form a stack of layers. In FIG. 7A, a white circle indicates a zinc atom, and a black circuit indicates an oxygen atom. By increasing the temperature of the heat treatment, crystal growth proceeds from the surface to the inside and further from the inside to the bottom. Further, FIG. 7B schematically shows a stack of six layers of two-dimensional crystal as an example of a stacked layer in which two-dimensional crystal has grown.

In the second deposition chamber, the second film including an oxide film can be formed by a sputtering method while the substrate is heated.

In the above, the second film may be an oxide semiconductor film. The oxide semiconductor preferably includes at least indium (In) or zinc (Zn). In particular, In and Zn are preferably included. As a stabilizer for reducing variation in electric characteristics of a transistor using the oxide semiconductor, gallium (Ga) is preferably additionally included. Tin (Sn) is preferably included as a stabilizer. Hafnium (Hf) is preferably included as a stabilizer. Aluminum (Al) is preferably included as a stabilizer.

As another stabilizer, one or plural kinds of lanthanoid such as lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), or lutetium (Lu) may be included.

As the oxide semiconductor, for example, indium oxide, tin oxide, zinc oxide, a two-component metal oxide such as an In—Zn-based oxide, a Sn—Zn-based oxide, an Al—Zn-based oxide, a Zn—Mg-based oxide, a Sn—Mg-based oxide, an In—Mg-based oxide, or an In—Ga-based oxide, a three-component metal oxide such as an In—Ga—Zn-based oxide (also referred to as IGZO), an In—Al—Zn-based oxide, an In—Sn—Zn-based oxide, a Sn—Ga—Zn-based oxide, an Al—Ga—Zn-based oxide, a Sn—Al—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, or an In—Lu—Zn-based oxide, or a four-component metal oxide such as an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, or an In—Hf—Al—Zn-based oxide can be used.

Note that here, for example, an “In—Ga—Zn-based oxide” means an oxide including In, Ga, and Zn as main components and there is no limitation on the ratio of In, Ga, and Zn. The In—Ga—Zn-based oxide may include a metal element other than In, Ga, and Zn.

Alternatively, a material expressed by the chemical formula InMO₃(ZnO), (m>0) may be used as the oxide semiconductor. Note that M represents one or more metal elements selected from Ga, Fe, Mn, and Co. Alternatively, as the oxide semiconductor, a material expressed by the chemical formula In₃SnO₅(ZnO)ₙ (n>0) may be used.

For example, an In—Ga—Zn-based oxide with an atomic ratio of In:Ga:Zn=1:1:1 (=1/3:1/3:1/3) or In:Ga:Zn=2:2:1 (=2/5:2/5:1/5), or any of oxides whose composition is in the neighborhood of the above compositions can be used. Alternatively, an In—Sn—Zn-based oxide with an atomic ratio of In:Sn:Zn=1:1:1 (=1/3:1/3:1/3), In:Sn:Zn=2:1:3 (=1/3:1/6:1/2), or In:Sn:Zn=2:1:5 (=1/4:1/8:5/8), or any of oxides whose composition is in the neighborhood of the above compositions may be used.

Note that for example, the expression “the composition of an oxide including In, Ga, and Zn at the atomic ratio, In:Ga:Zn=a:b:c (a+b+c=1), is in the neighborhood of the composition of an oxide including In, Ga, and Zn at the atomic ratio, In:Ga:Zn=A:B:C (A+B+C=1)” means that a, b, and c satisfy the following relation: (a−A)²+(b−B)²+(c−C)²≦², and r may be 0.05, for example. The same applies to other oxides.

By forming the second film over the first crystalline oxide semiconductor layer by a sputtering method with the substrate temperature in the film formation set to be higher than or equal to 200° C. and lower than or equal to 400° C., precursors can be arranged in the oxide semiconductor film formed over and in contact with a surface of the first crystalline oxide semiconductor layer and so-called orderliness can be obtained.

In the second heating chamber, heat treatment can be performed at a temperature higher than or equal to 400° C. and lower than or equal to 750° C. The heat treatment at a temperature higher than or equal to 400° C. and lower than or equal to 750° C. is performed on the substrate where the second oxide semiconductor film is formed over the first crystalline oxide semiconductor layer in a nitrogen atmosphere, an oxygen atmosphere, or a mixed atmosphere of nitrogen and oxygen, so that the density of a second oxide semiconductor layer is increased and the number of defects therein is reduced. By the second heat treatment, crystal growth proceeds in the thickness direction with the use of the first crystalline oxide semiconductor layer as a nucleus, that is, crystal growth proceeds upward from the bottom; thus, a second crystalline oxide semiconductor layer is formed.

A stack of the first crystalline oxide semiconductor layer and the second crystalline oxide semiconductor layer is obtained in this manner and is used for a transistor, for example, whereby the transistor can have stable electric characteristics and high reliability. Further, by setting the temperature of the first heat treatment and the second heat treatment to be 450° C. or lower, mass production of highly reliable semiconductor devices can be performed with the use of a large-sized substrate such as mother glasses of the fifth to twelfth generations.

The first crystalline oxide semiconductor layer formed with the deposition apparatus according to one embodiment of the present invention is characterized by having c-axis alignment. The second crystalline oxide semiconductor layer formed with the deposition apparatus according to one embodiment of the present invention is also characterized by having c-axis alignment. The first crystalline oxide semiconductor layer and the second crystalline oxide semiconductor layer comprise an oxide including a crystal with c-axis alignment (C-Axis Aligned Crystal), which has neither a single crystal structure nor an amorphous structure. The first crystalline oxide semiconductor layer and the second crystalline oxide semiconductor layer partly include a crystal grain boundary.

In the case of a transistor including the stack of the first crystalline oxide semiconductor layer and the second crystalline oxide semiconductor layer, even when the transistor is irradiated with light or subjected to a bias-temperature (BT) stress test, the amount of change in the threshold voltage of the transistor can be suppressed; thus, such a transistor has stable electric characteristics.

In the above deposition apparatus, the first deposition chamber, the second deposition chamber, the first heating chamber, and the second heating chamber are preferably evacuated with an entrapment vacuum pump. For example, a cryopump, an ion pump, or a titanium sublimation pump is preferably used. The above entrapment vacuum pump functions to reduce the amount of hydrogen, water, a hydroxyl group, or hydride included in the oxide semiconductor film. Since there is a possibility that hydrogen, water, a hydroxyl group, or hydride becomes one of factors inhibiting crystallization of the oxide semiconductor film, deposition, transfer of the substrate, and the like in the manufacturing process are preferably performed in an atmosphere where hydrogen, water, a hydroxyl group, or hydride is sufficiently reduced.

In all of the first deposition chamber, the second deposition chamber, the first heating chamber, and the second heating chamber, the substrate to be processed is held so that an angle formed by a deposition surface thereof and the vertical direction is at least in a range of greater than or equal to 1° and less than or equal to 30°, preferably greater than or equal to 5° and less than or equal to 15°. With such a structure in which treatment can be performed with the substrate standing, an increase in the floor area (so-called footprint) of the apparatus can be suppressed; accordingly, designing of a clean room is facilitated and cost can be suppressed. Moreover, with a structure in which the substrate can be held while being inclined slightly against the vertical direction, the substrate can be supported even under reduced pressure. Although use of a clamp can be given as a method for supporting the substrate without inclining it, this method has problems in that deposition is not performed on a substrate surface which overlaps with a clamp portion and in that dust is generated from the clamp portion.

In the above deposition apparatus, deposition treatment, heat treatment, and transfer are performed without exposure to the air; thus, the treatment and the transfer can always be performed in a clean atmosphere. Accordingly, the impurity concentration in a film and at an interface of the film can be extremely reduced and a highly reliable oxide semiconductor layer can be formed.

According to one embodiment of the present invention, a deposition apparatus with which a semiconductor device having stable electric characteristics and high reliability is realized can be provided. A deposition apparatus which enables mass production of highly reliable semiconductor devices with the use of a large-sized substrate such as a mother glass can be provided. A method for manufacturing a semiconductor device having stable electric characteristics and high reliability can be provided.

### BRIEF DESCRIPTION OF THE DRAWINGS

In the accompanying drawings:

FIGS. 1A and 1B are each a block diagram of a deposition apparatus for a semiconductor device, according to one embodiment of the present invention;

FIGS. 2A to 2C illustrate a deposition apparatus for a semiconductor device, according to one embodiment of the present invention;

FIGS. 3A and 3B illustrate a deposition apparatus for a semiconductor device, according to one embodiment of the present invention;

FIGS. 4A to 4F illustrate a method for forming a semiconductor layer, according to one embodiment of the present invention;

FIGS. 5A to 5C each illustrate a semiconductor layer according to one embodiment of the present invention;

FIGS. 6A to 6E illustrate a method for manufacturing a semiconductor device, according to one embodiment of the present invention;

FIGS. 7A and 7B are each a schematic view of two-dimensional crystal according to one embodiment of the present invention;

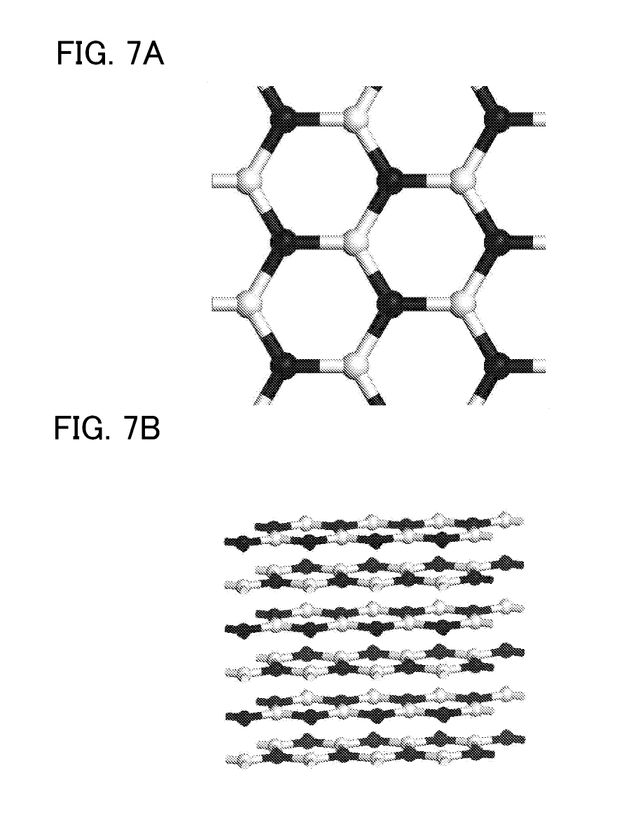

FIG. 8 shows results of measurement of negative-bias temperature stress photodegradation;

FIGS. 9A and 9B show results of measurement of photoresponse characteristics;

FIG. 10 is a schematic diagram of a donor level;

FIG. 11 shows results of low-temperature PL measurement;

FIGS. 12A to 12C are each a graph showing a g-factor;

FIG. 13 is a graph showing a g-factor;

FIG. 14 shows results of ESR measurement;

FIG. 15 shows results of ESR measurement;

FIG. 16 shows results of ESR measurement; and

FIG. 17 shows results of ESR measurement.

### DETAILED DESCRIPTION OF THE INVENTION

Embodiments will be described in detail with reference to drawings. Note that the present invention is not limited to the following description, and it will be easily understood by those skilled in the art that the modes and detail can be changed in various ways without departing from the spirit and scope of the present invention. Therefore, the present invention is not construed as being limited to the description in the following embodiments. Note that in the structures of the invention described below, the same portions or portions having similar functions are denoted by the same reference numerals in different drawings, and description of such portions is not repeated.

Note that in each drawing described in this specification, the size, the layer thickness, or the region of each component is exaggerated for clarity in some cases. Therefore, embodiments of the present invention are not limited to such scales.

### (Example of Deposition Apparatus)

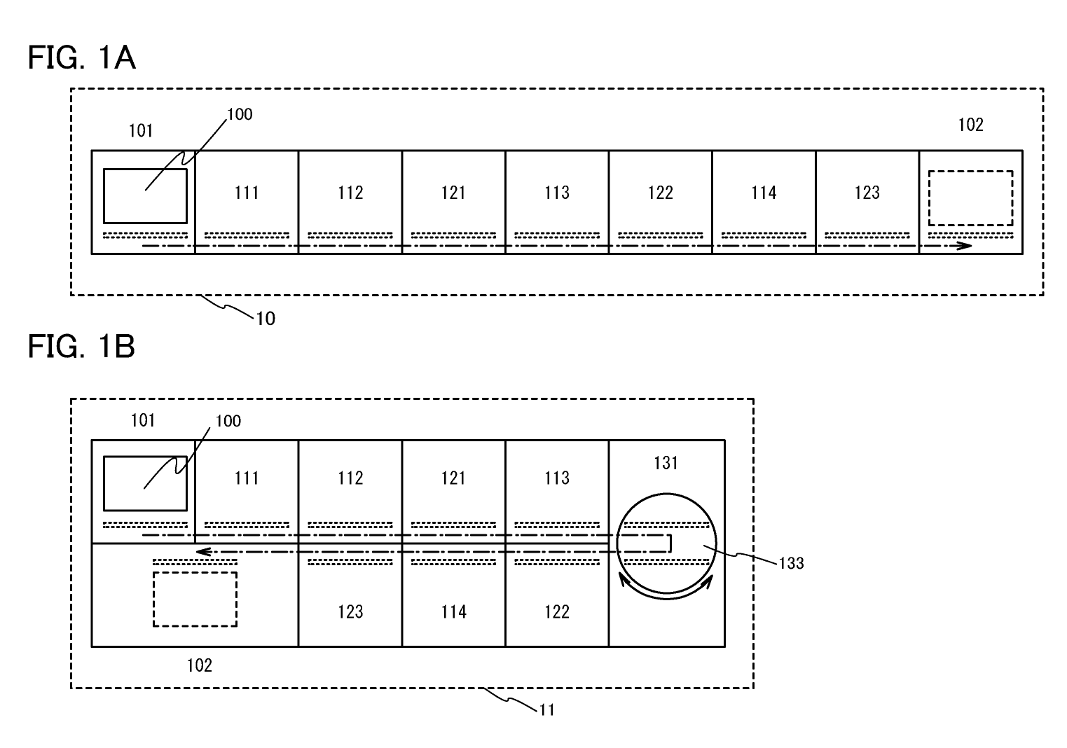

An example of a deposition apparatus with which an oxide semiconductor layer or the like is formed over a substrate will be described with reference to FIGS. 1A and 1B, FIGS. 2A to 2C, and FIGS. 3A and 3B.

FIG. 1A is a block diagram illustrating a structure of a deposition apparatus 10 described in this embodiment.

In the deposition apparatus 10, a load chamber 101, a first deposition chamber 111, a second deposition chamber 112, a first heating chamber 121, a third deposition chamber 113, a second heating chamber 122, a fourth deposition chamber 114, a third heating chamber 123, and an unload chamber 102 are connected in this order. Note that hereinafter, except for the load chamber 101 and the unload chamber 102, each deposition chamber and each heating chamber may be collectively referred to as a treatment chamber when there is no need to distinguish them from each other.

A substrate 100 carried into the load chamber 101 is transferred by a moving unit to each deposition chamber and each heating chamber in order from the first deposition chamber 111 to the third heating chamber 123, and then transferred to the unload chamber 102. Treatment is not necessarily performed in each treatment chamber, and the substrate may be transferred to the next treatment chamber as appropriate without being processed if a step is omitted.

The load chamber 101 has a function of receiving the substrate 100 from the outside into the deposition apparatus 10. The substrate 100 is carried horizontally into the load chamber 101, and then the substrate is made to stand vertically with respect to a horizontal plane by a mechanism provided in the load chamber 101. In FIG. 1A, the substrate 100 illustrated by a solid line indicates the state where the substrate is placed horizontally right after being carried into the load chamber, and a dashed line indicates the state where the substrate stands substantially vertically. Note that in the case where a unit for receiving the substrate 100, such as a robot, has a mechanism for making the substrate stand up, the load chamber 101 does not necessarily have the mechanism for making the substrate 100 stand up.

In contrast to the load chamber 101, the unload chamber 102 has a mechanism for laying the standing substrate 100 horizontally. After being processed, the substrate 100 is carried into the unload chamber by the moving unit. The standing substrate 100 is laid horizontally in the unload chamber 102, and then carried out of the apparatus. In FIG. 1A, both the standing substrate 100 and the horizontally placed substrate 100 are illustrated by a dashed line. Note that in the case where a unit for carrying the substrate 100 out of the apparatus, such as a robot, has a mechanism for laying the substrate, the unload chamber 102 does not necessarily have the mechanism for laying the substrate.

While being carried from the load chamber 101 to the unload chamber 102 through treatment in each treatment chamber, the substrate 100 is held so that an angle formed by a deposition surface of the substrate 100 and the vertical direction is in a range of greater than or equal to 1° and less than or equal to 30°, preferably greater than or equal to 5° and less than or equal to 15°. The substrate 100 is inclined slightly against the vertical direction in this manner, whereby a so-called footprint, which is the floor area of the apparatus, can be reduced. As the substrate size is increased to, for example, a size of the eleventh generation or the twelfth generation, such a structure becomes more effective in cost and facility of designing of a clean room or the like. Moreover, it is preferable that the substrate 100 be inclined slightly against the vertical direction because dust or particles attached to the substrate 100 can be reduced.

The load chamber 101 and the unload chamber 102 each have an evacuation unit for evacuating the chamber to vacuum and a gas introduction unit which is used when the vacuum state is changed to the atmospheric pressure. As a gas introduced by the gas introduction unit, air or an inert gas such as nitrogen or a rare gas may be used as appropriate.

The load chamber 101 may have a heating unit for preheating the substrate. By preheating the substrate in parallel with the evacuation step, impurities such as a gas (including water, a hydroxyl group, and the like) adsorbed to the substrate can be eliminated, which is preferable. As the evacuation unit, for example, an entrapment vacuum pump such as a cryopump, an ion pump, or a titanium sublimation pump or a turbo molecular pump provided with a cold trap may be used.

The load chamber 101, the unload chamber 102, and the treatment chambers are connected via gate valves. Therefore, when the substrate is transferred to the next treatment chamber after being processed, the gate valve is opened so that the substrate is carried thereinto. Note that this gate valve is not necessarily provided unless needed between the treatment chambers. Each treatment chamber has an evacuation unit, a pressure adjusting unit, a gas introduction unit, and the like; thus, the treatment chamber can always be clean and under reduced pressure even when treatment is not performed therein. A treatment chamber is isolated with the use of the gate valve and thus can be prevented from being contaminated by another treatment chamber.

In addition, the chambers of the deposition apparatus are not necessarily arranged in one line; for example, as illustrated in FIG. 1B, a deposition apparatus 11 in which a transfer chamber 131 is provided between adjacent treatment chambers and chambers are arranged in two lines may be employed. The transfer chamber 131 includes a turntable 133, so that the substrate carried into the transfer chamber can make a 180-degree turn and the path of the substrate can be turned. FIG. 1B illustrates a structure in which the transfer chamber 131 is provided between the third deposition chamber 113 and the second heating chamber 122; however, the transfer chamber 131 is not limited to being provided at the position and may be provided at a proper position in accordance with the size of each treatment chamber or the like.

Next, a structure common to the first deposition chamber 111, the second deposition chamber 112, the third deposition chamber 113, and the fourth deposition chamber 114 will be described. Then, similarly, a portion common to the first heating chamber 121, the second heating chamber 122, and the third heating chamber 123 will be described. Lastly, a feature of each treatment chamber will be described.

In the first deposition chamber, a sputtering apparatus or a CVD apparatus is provided. In each of the second deposition chamber, the third deposition chamber, and the fourth deposition chamber, a sputtering apparatus is provided.

As the sputtering apparatus used in the above deposition chamber, for example, a sputtering apparatus for a microwave sputtering method, an RF plasma sputtering method, an AC sputtering method, a DC sputtering method, or the like can be used.

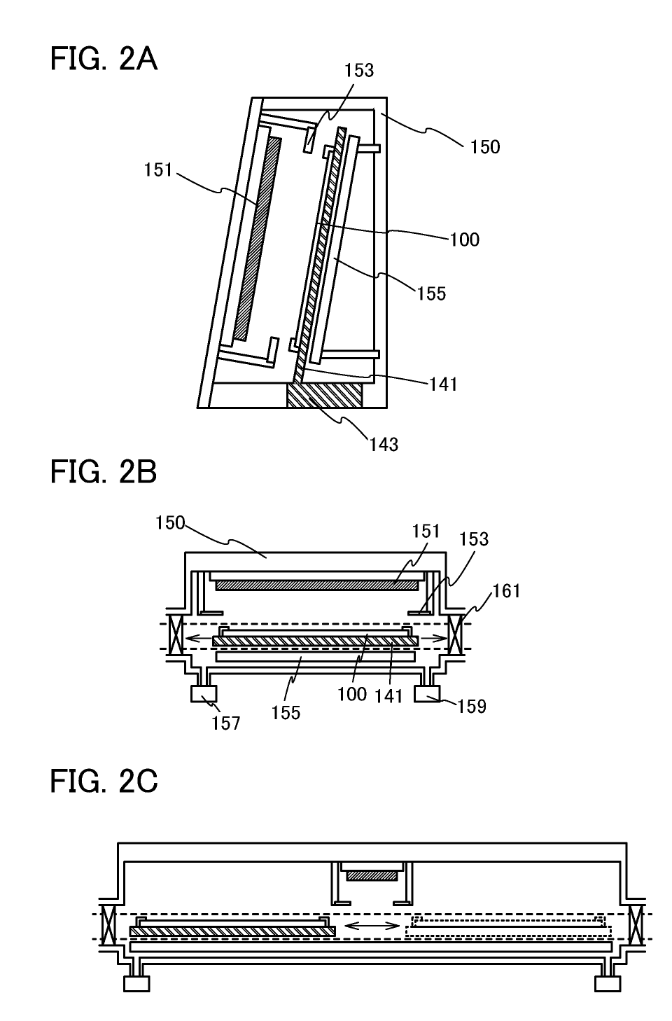

Here, an example of a deposition chamber using a DC sputtering method will be described with reference to FIGS. 2A to 2C. FIG. 2A is a schematic cross-sectional view of a deposition chamber 150 using a DC sputtering method, which is taken perpendicularly to the direction in which the substrate moves. FIG. 2B is a schematic cross-sectional view illustrating a cross section which is parallel and horizontal to the direction in which the substrate moves.

First, the substrate 100 is fixed by a substrate supporting portion 141 so that an angle formed by a deposition surface and the vertical direction is at least in a range of greater than or equal to 1° and less than or equal to 30°, preferably greater than or equal to 5° and less than or equal to 15°. The substrate supporting portion 141 is fixed to a moving unit 143. The moving unit 143 has a function of fixing the substrate supporting portion 141 so as to prevent the substrate from moving during treatment. Moreover, the moving unit 143 can move the substrate 100 along a dashed line in FIG. 2B (in the direction indicated by an arrow), and has a function of carrying the substrate 100 into and out of the load chamber 101, the unload chamber 102, and each treatment chamber.

In the deposition chamber 150, a target 151 and an attachment prevention plate 153 are arranged in parallel with the substrate 100. By arranging the target 151 and the substrate 100 in parallel, variation in the thickness of a sputtered film, variation in the step coverage with the sputtered film, and the like, which are caused owing to variation in the distance between the target and the substrate, can be reduced.

Further, the deposition chamber 150 may have a substrate heating unit 155 positioned behind the substrate supporting portion 141. With the substrate heating unit 155, deposition treatment can be performed while the substrate is heated. As the substrate heating unit 155, for example, a resistance heater, a lamp heater, or the like can be used. Note that the substrate heating unit 155 can be omitted when not needed.

The deposition chamber 150 has a pressure adjusting unit 157, and the pressure in the deposition chamber 150 can be reduced to a desired pressure. As an evacuation apparatus used for the pressure adjusting unit, for example, an entrapment vacuum pump such as a cryopump, an ion pump, or a titanium sublimation pump or a turbo molecular pump provided with a cold trap may be used.

Further, the deposition chamber 150 has a gas introduction unit 159 for introducing a deposition gas or the like. For example, an oxide film can be formed in such a manner that a gas which includes a rare gas as a main component and to which oxygen is added is introduced, and deposition is performed by a reactive sputtering method. As the gas introduced by the gas introduction unit 159, a high-purity gas in which impurities such as hydrogen, water, and hydride are reduced can be used. For example, oxygen, nitrogen, a rare gas (typically argon), or a mixed gas of any of these can be introduced.

In the deposition chamber 150 having the pressure adjusting unit 157 and the gas introduction unit 159, a hydrogen molecule, a compound including hydrogen such as water (H₂O), (preferably, also a compound including a carbon atom), and the like are removed. Accordingly, the concentration of impurities in a film formed in the deposition chamber can be reduced.

The deposition chamber 150 and an adjacent chamber are separated by a gate valve 161. The chamber is isolated using the gate valve 161, so that impurities in the chamber can be easily eliminated and a clean deposition atmosphere can be maintained. Moreover, the gate valve is opened and the substrate is carried out of the chamber after the chamber is made clean, whereby contamination of an adjacent treatment chamber can be suppressed. Note that the gate valve 161 can be omitted when not needed.

Note that the deposition chamber 150 may have a structure in which deposition is performed while the substrate 100 is slid along a dashed line in the drawing, i.e., in the direction of an arrow as illustrated in FIG. 2C. With such a structure, the size of the target can be reduced; therefore, such a structure is suitable for the case where a large-sized substrate is used but the size of a target cannot be approximately as large as the size of the substrate.

In the first heating chamber 121, the second heating chamber 122, and the third heating chamber 123, heat treatment can be performed on the substrate 100.

An apparatus using a resistance heater, a lamp, a heated gas, or the like may be provided as a hating apparatus.

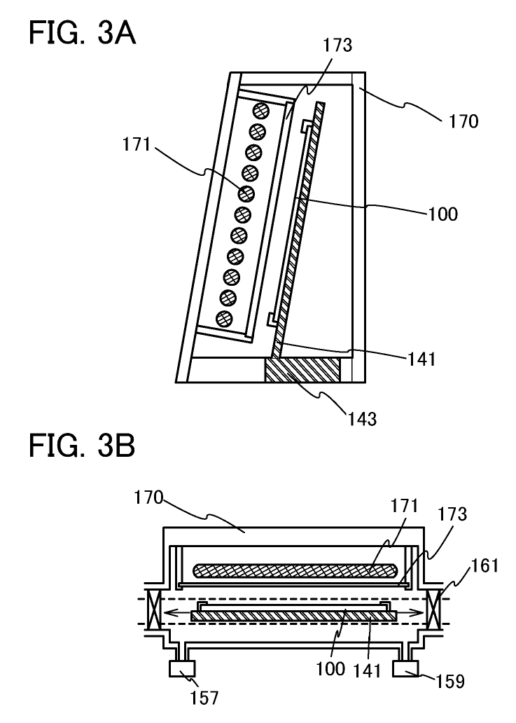

FIGS. 3A and 3B illustrate an example of a heating chamber to which a heating apparatus using a rod-shaped heater is applied. FIG. 3A is a schematic cross-sectional view of a heating chamber 170, which illustrates to a cross section perpendicular to the direction in which the substrate moves. FIG. 3B is a schematic cross-sectional view illustrating a cross section horizontal to the direction in which the substrate moves.

As in the deposition chamber 150, the substrate 100 supported by the substrate supporting portion 141 can be carried into and out of the heating chamber 170 by the moving unit 143.

In the heating chamber 170, rod-shaped heaters 171 are arranged in parallel with the substrate 100. FIG. 3A schematically illustrates the shape of a cross section of the rod-shaped heater 171. A resistance heater or a lamp heater can be used as the rod-shaped heater 171. The resistance heater includes the one using introduction heating. Further, it is preferable to use a lamp whose light has a center wavelength in the infrared region. By arranging the rod-shaped heaters 171 in parallel with the substrate 100, the distance therebetween can be uniform and heating can be performed uniformly. In addition, it is preferable that the temperature of the rod-shaped heaters 171 be individually controlled. For example, when a heater in a lower portion is set at a higher temperature than a heater in an upper portion, the substrate can be heated at a uniform temperature. Note that the rod-shaped heater is used in this embodiment; however, the heater is not limited to having this structure and a planar (plate-shaped) heater may be used. Further, heat treatment can be performed while such a heater is moved. Alternatively, a heating method using a laser may be used.

In the heating chamber 170, a protection plate 173 is provided between the rod-shaped heaters 171 and the substrate 100. The protection plate 173 is provided in order to protect the rod-shaped heaters 171 and the substrate 100 and can be formed using quartz or the like, for example. The protection plate 173 is not necessarily provided unless needed. Note that a shutter plate is not provided between the rod-shaped heaters 171 and the substrate 100 in this structure, and thus the entire surface of the substrate can be uniformly heated.

Further, the heating chamber 170 has the pressure adjusting unit 157 and the gas introduction unit 159 as in the deposition chamber 150. Therefore, the heating chamber 170 can always be clean and under reduced pressure during heat treatment and even when treatment is not performed therein. In the heating chamber 170, a hydrogen molecule, a compound including hydrogen such as water (H₂O), (preferably, also a compound including a carbon atom), and the like are removed, whereby the concentration of impurities in a film processed in the heating chamber, those at an interface of the film, or those included in or adsorbed to a surface of the film can be reduced.

With the pressure adjusting unit 157 and the gas introduction unit 159, heat treatment in an inert gas atmosphere or an atmosphere including oxygen can be performed. Note that as the inert gas atmosphere, an atmosphere that includes nitrogen or a rare gas (such as helium, neon, or argon) as a main component and does not include water, hydrogen, and the like is preferably used. For example, the purity of nitrogen or a rare gas such as helium, neon, or argon introduced into the heating chamber 170 is 6N (99.9999%) or higher, preferably 7N (99.99999%) or higher (i.e., the impurity concentration is 1 ppm or lower, preferably 0.1 ppm or lower).

Next, a feature and a structure which are peculiar in each treatment chamber will be described.

In the first deposition chamber 111, an oxide insulating film is formed over the substrate. A deposition apparatus may be either a sputtering apparatus or a CVD apparatus. A film that can be formed in the first deposition chamber 111 may be any film functioning as a base layer or a gate insulating layer of a transistor or the like; for example, a film of silicon oxide, silicon oxynitride, silicon nitride oxide, aluminum oxide, gallium oxide, aluminum oxynitride, aluminum nitride oxide, hafnium oxide, or the like, a mixed film of any of these, and the like can be given.

In the case of a sputtering apparatus, for example, a proper target may be used in accordance with the kind of the film. In the case of a CVD apparatus, a deposition gas is selected as appropriate.

In the second deposition chamber 112, an oxide film can be formed by a sputtering method. As the oxide film formed here, for example, a film of an oxide of zinc and gallium, and the like can be given. As a deposition method, a microwave plasma sputtering method, an RF plasma sputtering method, an AC sputtering method, or a DC sputtering method can be used.

In the second deposition chamber 112, deposition can be performed while the substrate is heated by the substrate heating unit 155 to a temperature of 600° C. or lower.

In the first heating chamber, the substrate can be heated at a temperature higher than or equal to 200° C. and lower than or equal to 700° C. Furthermore, with the pressure adjusting unit 157 and the gas introduction unit 159, heat treatment can be performed in an oxygen atmosphere, a nitrogen atmosphere, or a mixed atmosphere of oxygen and nitrogen, whose pressure is set to 10 Pa to 1 normal atmospheric pressure, for example.

In the third deposition chamber, an oxide semiconductor film is formed over the substrate 100. An example of the oxide semiconductor is an oxide semiconductor including at least Zn, and an oxide semiconductor such as an In—Ga—Zn—O-based oxide semiconductor given above can be deposited.

Deposition can be performed while the substrate is heated by the substrate heating unit 155 at a deposition temperature higher than or equal to 200° C. and lower than or equal to 600° C.

In the second heating chamber 122, the substrate 100 can be heated at a temperature higher than or equal to 200° C. and lower than or equal to 700° C.

Furthermore, with the pressure adjusting unit 157 and the gas introduction unit 159, heat treatment can be performed in an atmosphere where oxygen or nitrogen is included and impurities such as hydrogen, water, and a hydroxyl group are extremely reduced under a pressure higher than or equal to 10 Pa and lower than or equal to 1 normal atmospheric pressure.

In the fourth deposition chamber, an oxide semiconductor film is formed over the substrate 100 as in the third deposition chamber. For example, an In—Ga—Zn—O-based oxide semiconductor film can be formed using a target for an In—Ga—Zn—O-based oxide semiconductor. In addition, deposition can be performed while the substrate is heated at a temperature higher than or equal to 200° C. and lower than or equal to 600° C.

Finally, in the third heating chamber, heat treatment can be performed on the substrate 100 at a temperature higher than or equal to 400° C. and lower than or equal to 750° C.

Furthermore, with the pressure adjusting unit 157 and the gas introduction unit 159, the heat treatment can be performed in a nitrogen atmosphere, an oxygen atmosphere, or a mixed atmosphere of nitrogen and oxygen.

The deposition apparatus described in this embodiment has a structure in which exposure to the air is thoroughly prevented, from the load chamber through each treatment chamber to the unload chamber, and the substrate can always be transferred under clean and reduced-pressure environment. Therefore, entry of an impurity into an interface of a film formed with this deposition apparatus can be suppressed, so that a film whose interfacial state is extremely favorable can be formed.

An oxide semiconductor layer which is formed with the deposition apparatus 10 described in this embodiment by a method shown below or the like is used for a semiconductor device such as a transistor, whereby a semiconductor device having stable electric characteristics and high reliability can be realized. Moreover, with the deposition apparatus 10 described in this embodiment, formation steps of an oxide semiconductor layer can be successively performed without exposure to the air even on a large-sized substrate such as a mother glass with the use of a series of apparatuses in which the impurity concentration is reduced.

This embodiment can be implemented in an appropriate combination with any of the other embodiments described in this specification.

### (Example of Method for Forming Oxide Semiconductor Layer)

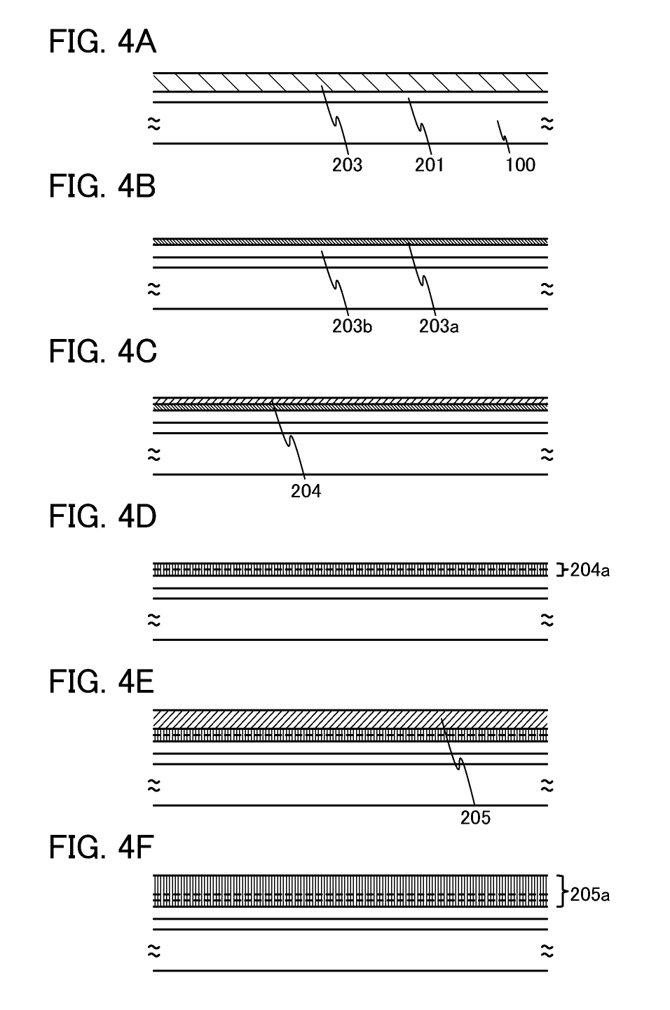

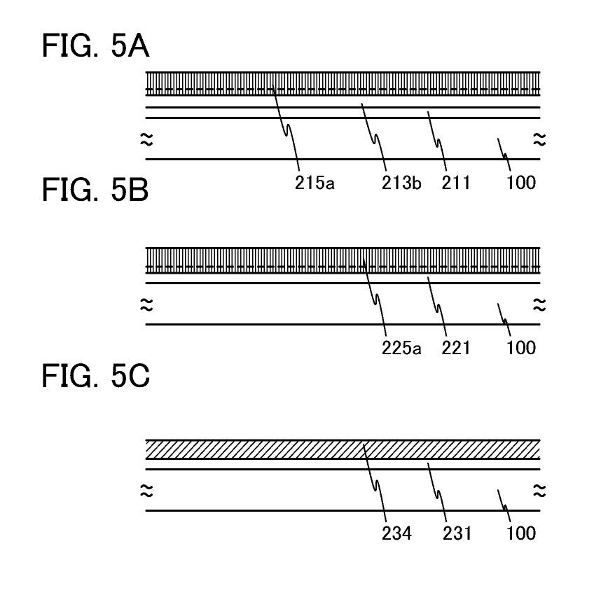

In this embodiment, an example of a method for forming an oxide semiconductor layer over an insulating layer with the use of the above-described deposition apparatus will be described with reference to FIGS. 4A to 4F and FIGS. 5A to 5C. The method is supposed to be applied to a thin film transistor.

First, the substrate 100 illustrated in FIGS. 1A and 1B is carried into the load chamber 101.

As the substrate 100, a non-alkali glass substrate formed by a fusion method or a float method, or the like can be used. As the substrate 100, a large-sized mother glass of any of the fifth to twelfth generations, preferably the eighth to twelfth generations, can be used.

After the substrate 100 is carried into the load chamber 101, the load chamber 101 is evacuated to vacuum. Here, when the load chamber is evacuated while preheating is performed therein, a gas (including impurities such as a hydrogen molecule, water, and a hydroxyl group) adsorbed to the substrate 100 can be removed.

Next, an oxide insulating layer 201 is formed by a sputtering method or a CVD method in the first deposition chamber 111. The oxide insulating layer 201 is formed using any of silicon oxide, silicon oxynitride, silicon nitride oxide, aluminum oxide, gallium oxide, aluminum oxynitride, aluminum nitride oxide, and hafnium oxide, or a mixed material of any of these. The thickness of the oxide insulating layer 201 is greater than or equal to 10 nm and less than or equal to 200 nm.

In this embodiment, a 100-nm-thick silicon oxide film is formed by a sputtering method and used as the oxide insulating layer 201.

Then, the substrate is transferred to the second deposition chamber 112, and an oxide film 203 is formed. The oxide film 203 is formed by a microwave plasma sputtering method, an RF plasma sputtering method, an AC sputtering method, or a DC sputtering method. Which method to employ may be determined in consideration of the conductivity of a target, the size of the target, the area of the substrate, or the like.

As for a target, in the case where the oxide film 203 is an oxide of gallium and zinc, an oxide in which the rates of gallium and zinc are adjusted so that the rate of gallium, Ga/(Ga+Zn) is greater than or equal to 0.2 and less than 0.8, preferably greater than or equal to 0.3 and less than 0.7, may be used. Note that it is generally known that the composition of a target is different from the composition of an obtained film depending on an atmosphere and temperature of a deposition surface; for example, even when a conductive target is used, the concentration of zinc of the obtained film is decreased, so that the obtained film has an insulating property or semiconductivity in some cases.

In this embodiment, an oxide of zinc and gallium is used; the vapor pressure of zinc at a temperature higher than or equal to 200° C. is higher than that of gallium. Therefore, when the substrate 100 is heated at 200° C. or higher, the concentration of zinc of the oxide film 203 is lower than the concentration of zinc of the target. Accordingly, in consideration of the fact, it is necessary that the concentration of zinc of the target be set at a higher concentration. When the concentration of zinc is increased, in general, the conductivity of an oxide is improved; therefore, a DC sputtering method is preferably used.

The target for sputtering can be obtained in the following manner: after a powder of gallium oxide and a powder of zinc oxide are mixed and pre-baked, molding is performed; then, baking is performed. Alternatively, a powder of gallium oxide whose grain size is 100 nm or less and a powder of zinc oxide whose grain size is 100 nm or less may be mixed sufficiently and molded.

The oxide film 203 is preferably formed by a method with which hydrogen, water, and the like do not easily enter the oxide film 203. The deposition atmosphere may be a rare gas (typically argon) atmosphere, an oxygen atmosphere, a mixed atmosphere of a rare gas and oxygen, or the like. An atmosphere of a high-purity gas from which impurities such as hydrogen, water, a hydroxyl group, and hydride are sufficiently removed is preferable, in order to prevent hydrogen, water, a hydroxyl group, hydride, and the like from entering the oxide film 203.

The entry of the impurities can also be prevented when the substrate temperature in the film formation is set to be higher than or equal to 100° C. and lower than or equal to 600° C., preferably higher than or equal to 200° C. and lower than or equal to 400° C. In addition, an entrapment vacuum pump such as a cryopump, an ion pump, or a titanium sublimation pump or a turbo molecular pump provided with a cold trap may be used as an evacuation unit. By evacuation using the above evacuation unit, a hydrogen molecule, a compound including a hydrogen atom such as water, (preferably, also a compound including a carbon atom), and the like are removed. Accordingly, the concentration of impurities in the oxide film 203 formed in the deposition chamber can be reduced.

FIG. 4A is a schematic cross-sectional view at this stage.

Next, the substrate is carried into the first heating chamber 121, and first heat treatment is performed.

In the first heating chamber 121, heat treatment is performed at 400° C. to 700° C. for 10 minutes to 24 hours under the condition where the pressure is 10 Pa to 1 normal atmospheric pressure and the atmosphere is any of an oxygen atmosphere, a nitrogen atmosphere, and a mixed atmosphere of oxygen and nitrogen, for example. Then, as illustrated in FIG. 4B, the quality of the oxide film 203 is changed, so that an oxide semiconductor layer 203a having a high concentration of zinc is formed in the vicinity of a surface, and the other portion becomes an oxide insulating layer 203b having a low concentration of zinc.

Note that as the heating time is longer, heating temperature is higher, and the pressure at the time of heating is lower, zinc is easily evaporated and the oxide semiconductor layer 203a tends to be thin.

The thickness of the oxide semiconductor layer 203a is preferably 3 nm to 15 nm. The thickness of the oxide semiconductor layer 203a can be controlled by heating time, heating temperature, and pressure at the time of heating as described above, or by the composition and thickness of the oxide film 203. The composition of the oxide film 203 can be controlled by substrate temperature in the film formation as well as the composition of the target; therefore, these may be set as appropriate.

The obtained oxide semiconductor layer 203a has crystallinity; in an X-ray diffraction analysis of a crystal structure, the ratio of the diffraction intensity of an a-plane or a b-plane to the diffraction intensity of a c-plane is greater than or equal to 0 and less than or equal to 0.3, and thus the oxide semiconductor layer 203a has c-axis alignment. In this embodiment, the oxide semiconductor layer 203a is an oxide in which zinc is a main metal component.

On the other hand, the rate of gallium, Ga/(Ga+Zn) in the oxide insulating layer 203b may be 0.7 or more, preferably 0.8 or more. Note that the rate of gallium in the oxide insulating layer 203b in a portion close to the surface, for example, in a portion in contact with the oxide semiconductor layer 203a has the lowest value and the rate is increased toward the substrate. In contrast, the rate of zinc in the portion close to the surface has the highest value and the rate is decreased toward the substrate.

Note that in this heat treatment, an alkali metal such as lithium, sodium, or potassium is also segregated in the vicinity of the surface of the oxide semiconductor layer 203a and evaporated; therefore, the concentration in the oxide semiconductor layer 203a and the concentration in the oxide insulating layer 203b are sufficiently reduced. These alkali metals are unfavorable elements for a transistor; thus, it is preferable that these alkali metals be included in a material used for forming the transistor as few as possible. Since these alkali metals are easily evaporated compared to zinc; therefore, a heat treatment step is effective in removing these alkali metals.

Through such treatment, for example, the concentration of sodium in each of the oxide semiconductor layer 203a and the oxide insulating layer 203b may be 5×10¹⁶ cm⁻³ or lower, preferably 1×10¹⁶ cm⁻³ or lower, further preferably 1×10¹⁵ cm⁻³ or lower. Similarly, the concentration of lithium in each of the oxide semiconductor layer 203a and the oxide insulating layer 203b may be 5×10¹⁵ cm⁻³ or lower, preferably 1×10¹⁵ cm⁻³ or lower; the concentration of potassium in each of the oxide semiconductor layer 203a and the oxide insulating layer 203b may be 5×10¹⁵ cm⁻³ or lower, preferably 1×10¹⁵ cm⁻³ or lower.

Then, the substrate is transferred to the third deposition chamber, and an oxide semiconductor film 204 is formed. In this embodiment, an indium-gallium-zinc-based oxide is employed as the oxide semiconductor. In other words, the oxide semiconductor film 204 is formed by a sputtering method using an indium-gallium-zinc-based oxide as a target.

The filling rate of the oxide target is higher than or equal to 90% and lower than or equal to 100%, preferably higher than or equal to 95% and lower than or equal to 99%. With the use of the oxide target with a high filling rate, the obtained oxide semiconductor film can have high density. As for a composition ratio of the target, for example, an In—Ga—Zn—O target having an atomic ratio of In:Ga:Zn=1:1:1, 4:2:3, 3:1:2, 1:1:2, 2:1:3, or 3:1:4 is used. Note that it is not necessary to limit the material and the composition ratio of the target to this. For example, an oxide target having a composition ratio of In:Ga:Zn=1:1:0.5 [molar ratio] may be used.

As described later, as for the composition of the obtained oxide semiconductor film, it is preferable that the rate of gallium in the metal components (molar ratio) be 0.2 or more. For example, in the case where In:Ga:Zn=1:1:2, the rate of gallium is 0.25; in the case where In:Ga:Zn=1:1:1, the rate of gallium is 0.33; and in the case where In:Ga:Zn=1:1:0.5, the rate of gallium is 0.4.

The oxide semiconductor film 204 is preferably formed by a method with which hydrogen, water, and the like do not easily enter the oxide semiconductor film 204. The deposition atmosphere may be a rare gas (typically argon) atmosphere, an oxygen atmosphere, or a mixed atmosphere of a rare gas and oxygen. An atmosphere of a high-purity gas from which impurities such as hydrogen, water, a hydroxyl group, and hydride are sufficiently removed is preferable, in order to prevent hydrogen, water, a hydroxyl group, hydride, and the like from entering the oxide semiconductor film 204.

The thickness of the oxide semiconductor film 204 is preferably greater than or equal to 3 nm and less than or equal to 30 nm. This is because the transistor might be normally on when the oxide semiconductor film is too thick (e.g., the thickness is 50 nm or more).

The substrate temperature in the formation of the oxide semiconductor film 204 is higher than or equal to 100° C. and lower than or equal to 600° C., preferably higher than or equal to 200° C. and lower than or equal to 400° C., further preferably higher than or equal to 250° C. and lower than or equal to 300° C. It is preferable that the substrate temperature in the film formation be high because entry of impurities described above can be suppressed.

In addition, an entrapment vacuum pump such as a cryopump, an ion pump, or a titanium sublimation pump or a turbo molecular pump provided with a cold trap may be used as an evacuation unit. In the deposition chamber which is evacuated with such an evacuation unit, a hydrogen molecule, a compound including a hydrogen atom such as water (H₂O), (preferably, also a compound including a carbon atom), and the like are removed, whereby the concentration of an impurity in the oxide semiconductor film 204 formed in the deposition chamber can be reduced.

An alkali metal such as lithium, sodium, or potassium or an alkaline earth metal is an unfavorable element in the case where an oxide semiconductor is used for a transistor; therefore, it is preferable that an alkali metal or an alkaline earth metal be included in a material used for forming the transistor as few as possible.

Of alkali metals, in particular, sodium is diffused in an oxide insulator which is in contact with an oxide semiconductor to be a sodium ion. Sodium cuts a bond between a metal element and oxygen or enters the bond in the oxide semiconductor. As a result, transistor characteristics deteriorate (e.g., the transistor becomes normally on (the threshold voltage is shifted to a negative side) or the mobility is decreased). In addition, this also causes variation in characteristics.

Such a problem is significant especially in the case where the hydrogen concentration in the oxide semiconductor is extremely low. Therefore, the concentration of an alkali metal is strongly required to be sufficiently reduced in the case where the hydrogen concentration in the oxide semiconductor is 5×10¹⁹ cm⁻³ or lower, in particular, 5×10¹⁸ cm⁻³ or lower.

For example, the concentration of sodium in the oxide semiconductor film 204 may be 5×10¹⁶ cm⁻³ or lower, preferably 1×10¹⁶ cm⁻³ or lower, further preferably 1×10¹⁵ cm⁻³ or lower. Similarly, the concentration of lithium in the oxide semiconductor film 204 may be 5×10¹⁵ cm⁻³ or lower, preferably 1×10¹⁵ cm⁻³ or lower; the concentration of potassium in the oxide semiconductor film 204 may be 5×10¹⁵ cm⁻³ or lower, preferably 1×10¹⁵ cm⁻³ or lower.

FIG. 4C is a schematic cross-sectional view at this stage.

Next, the substrate 100 is transferred to the second heating chamber 122, and second heat treatment is performed.

By performing the second heat treatment on the oxide semiconductor film 204, crystal growth occurs in the oxide semiconductor film 204 with the use of crystal in the oxide semiconductor layer 203a as a nucleus, so that the oxide semiconductor layer 203a and the oxide semiconductor film 204 are combined and a c-axis-aligned crystalline oxide semiconductor layer 204a is formed as illustrated in FIG. 4D.

At the same time, excessive hydrogen (including water and a hydroxyl group) in the oxide semiconductor film 204 is removed and a structure of the oxide semiconductor film 204 is improved, so that defect levels in the energy gap can be reduced.

Further, excessive hydrogen (including water and a hydroxyl group) in the oxide insulating layer 201 and the oxide insulating layer 203b can also be removed by the second heat treatment. The temperature of the second heat treatment is higher than or equal to 250° C. and lower than or equal to 650° C., preferably higher than or equal to 300° C. and lower than or equal to 500° C.

Note that a dashed line in FIG. 4D indicates an interface between the oxide semiconductor film 204 and the oxide semiconductor layer 203a; however, since the oxide semiconductor layer 203a and the oxide semiconductor film 204 are combined to be the oxide semiconductor layer 204a as a result of the second heat treatment, the interface is not distinct.

Next, the substrate is carried into the fourth deposition chamber 114, and an oxide semiconductor film 205 is formed over the oxide semiconductor layer 204a by a method similar to that used in the third deposition chamber 113.

The oxide semiconductor can be deposited using the above target for an oxide semiconductor. In this embodiment, a target for an In—Ga—Zn—O-based oxide semiconductor (In:Ga:Zn=1:1:1 [molar ratio]) is used, the substrate temperature is set to be higher than or equal to 100° C. and lower than or equal to 600° C., preferably higher than or equal to 200° C. and lower than or equal to 400° C., further preferably higher than or equal to 250° C. and lower than or equal to 300° C., and the oxide semiconductor film 205 is formed to a thickness of 10 nm or more (see FIG. 4E).

Then, the substrate 100 is transferred to the third heating chamber 123, and third heat treatment is performed.

The third heat treatment is performed at a temperature higher than or equal to 400° C. and lower than or equal to 750° C. for longer than or equal to 1 minute and shorter than or equal to 24 hours in a nitrogen atmosphere or dry air.

By the third heat treatment, crystal growth occurs in the oxide semiconductor film 205 with the use of crystal in the oxide semiconductor layer 204a as a nucleus. As a result, the oxide semiconductor film 205 and the oxide semiconductor layer 204a are combined to be an oxide semiconductor layer 205a. FIG. 4F is a schematic cross-sectional view illustrating this state. Here, a dashed line in the oxide semiconductor layer 205a indicates an interface between the oxide semiconductor film 205 and the oxide semiconductor layer 204a; however, the interface is actually not distinct.

Note that the oxide insulating layer 203b in which gallium is a main metal element is used in this embodiment. When such a material is in contact with an oxide semiconductor in which, in particular, the rate of gallium in the metal elements is 0.2 or more, charge trapping at an interface between the oxide insulating layer 203b and an oxide semiconductor film can be sufficiently suppressed. By using such a film in a semiconductor device, a highly reliable semiconductor device can be provided.

Finally, the substrate 100 is carried into the unload chamber 102, and the process is completed.

Through the above series of steps, the oxide semiconductor layer 205a having c-axis alignment and an extremely reduced impurity concentration can be formed over the substrate 100. The semiconductor layer having c-axis alignment and an extremely reduced impurity concentration, which is formed with the deposition apparatus, is used for a semiconductor device such as a transistor, whereby a semiconductor device having stable electric characteristics and high reliability can be realized.

Here, all the deposition chambers and heating chambers which are included in the above deposition apparatus are used to form the oxide semiconductor layer in this embodiment; when a combination of a deposition chamber and a heating chamber which are used is changed, a plurality of manufacturing steps can be performed and a variety of oxide semiconductor layers can be formed. A method for forming an oxide semiconductor layer, in which the deposition chambers and the heating chambers included in the deposition apparatus are selectively used, will be described below as a modification example.

### Modification Example 1

A method for forming an oxide insulating layer 211, an oxide insulating layer 213b, and an oxide semiconductor layer 215a having c-axis-aligned crystallinity, which are illustrated in FIG. 5A, over the substrate 100 will be described.

Steps up to and including the step of performing the first heat treatment in the first heating chamber 121 are performed in a manner similar to that of the foregoing example. In other words, the oxide insulating layer 211 is formed in the first deposition chamber 111, an oxide film is formed over the oxide insulating layer in the second deposition chamber 112, and the first heat treatment is performed in the first heating chamber 121. By the first heat treatment, a lower layer of the oxide film becomes the oxide insulating layer 213b and an upper layer thereof becomes an oxide semiconductor layer having c-axis aligned crystallinity.

Next, in the third deposition chamber 113, an oxide semiconductor film is formed while the substrate 100 is heated. For example, the oxide semiconductor film is formed to a thickness of 30 nm in an oxygen atmosphere, an argon atmosphere, or an atmosphere including argon and oxygen under the condition where a target for an oxide semiconductor (a target for an In—Ga—Zn—O-based oxide semiconductor (In₂O₃:Ga₂O₃:ZnO=1:1:1 [molar ratio])) is used, the distance between the substrate and the target is 170 mm, the substrate temperature is 250° C., the pressure is 0.4 Pa, and the direct current (DC) power is 0.5 kW.

Next, second heat treatment is performed in the second heating chamber 122. The temperature of the second heat treatment is 200° C. or higher, preferably higher than or equal to 400° C. and lower than or equal to 700° C. By the second heat treatment, crystal growth occurs in the above oxide semiconductor film with the use of the oxide semiconductor layer having c-axis-aligned crystallinity as a nucleus, so that the oxide semiconductor layer 215a which has c-axis-aligned crystallinity and includes no interface can be formed.

After that, the substrate 100 is only transferred through the fourth deposition chamber 114 and the third heating chamber 123 without being processed therein, and the substrate 100 is carried into the unload chamber 102.

Through the above steps, an oxide semiconductor layer having c-axis alignment and an extremely reduced impurity concentration can be formed.

### Modification Example 2

A method for forming an oxide insulating layer 221 and an oxide semiconductor layer 225a having c-axis alignment, which are illustrated in FIG. 5B, over the substrate 100 will be described.

First, the substrate is transferred from the load chamber 101 to the first deposition chamber 111, and the oxide insulating layer 221 is formed. After that, the substrate is only transferred through the second deposition chamber 112 without being processed therein. Then, the substrate is carried into the first heating chamber 121 and first heat treatment is performed. By the first heat treatment, impurities such as hydrogen, water, and a hydroxyl group in the oxide insulating layer 221 can be removed. Note that it is also possible for second heat treatment performed later to serve as the first heat treatment, without performing the first heat treatment.

Then, in the third deposition chamber 113, a first oxide semiconductor film having a thickness greater than or equal to 1 nm and less than or equal to 10 nm is formed at a substrate temperature higher than or equal to 200° C. and lower than or equal to 400° C. For example, the first oxide semiconductor film is formed to a thickness of 5 nm in an oxygen atmosphere, an argon atmosphere, or an atmosphere including argon and oxygen under the condition where a target for an oxide semiconductor (a target for an In—Ga—Zn—O-based oxide semiconductor (In₂O₃:Ga₂O₃:ZnO=1:1:2 [molar ratio])) is used, the distance between the substrate and the target is 170 mm, the substrate temperature is 250° C., the pressure is 0.4 Pa, and the direct current (DC) power is 0.5 kW.

After that, second heat treatment is performed in the second heating chamber 122, so that the first oxide semiconductor film becomes a crystalline oxide semiconductor film having c-axis alignment. The second heat treatment is preferably performed at a temperature higher than or equal to 400° C. and lower than or equal to 750° C. in a nitrogen atmosphere or dry air. In the case where the first heat treatment is not performed, impurities including hydrogen in the oxide insulating layer can be removed by the second heat treatment.

Next, a second oxide semiconductor film having a thickness greater than 10 nm is formed in the fourth deposition chamber 114. For example, the second oxide semiconductor film is formed to a thickness of 25 nm in an oxygen atmosphere, an argon atmosphere, or an atmosphere including argon and oxygen under the condition where a target for an oxide semiconductor (a target for an In—Ga—Zn—O-based oxide semiconductor (In₂O₃:Ga₂O₃:ZnO=1:1:2 [molar ratio])) is used, the distance between the substrate and the target is 170 mm, the substrate temperature is 400° C., the pressure is 0.4 Pa, and the direct current (DC) power is 0.5 kW.

By forming the second oxide semiconductor film with the substrate temperature set to be higher than or equal to 200° C. and lower than or equal to 400° C., precursors can be arranged in the oxide semiconductor film formed over and in contact with a surface of the first oxide semiconductor film and so-called orderliness can be obtained.

Then, third heat treatment is performed in the third heating chamber 123. The third heat treatment is performed at a temperature higher than or equal to 400° C. and lower than or equal to 750° C. for longer than or equal to 1 minute and shorter than or equal to 24 hours in an atmosphere of nitrogen or dry air, so that the crystalline oxide semiconductor layer 225a having c-axis alignment can be formed.

Through the above steps, an oxide semiconductor layer having c-axis alignment and an extremely reduced impurity concentration can be formed.

### Modification Example 3

A method for forming an oxide insulating layer 231 and an oxide semiconductor layer 234, which are illustrated in FIG. 5C, over the substrate 100 will be described.

First, the substrate 100 is transferred from the load chamber 101 to the first deposition chamber 111, and the oxide insulating layer 231 is formed. As the oxide insulating layer 231, for example, a 100-nm-thick silicon oxide film is formed by a sputtering method.

Then, the substrate is only transferred through the second deposition chamber 112 without being processed therein, and first heat treatment is performed in the first heating chamber 121. By the first heat treatment, impurities such as hydrogen, water, and a hydroxyl group in the oxide insulating layer 231 can be removed. Note that it is also possible for second heat treatment performed later to serve as the first heat treatment, without performing the first heat treatment.

Next, the substrate is transferred to the third deposition chamber 113, and the oxide semiconductor layer 234 is formed. For example, the oxide semiconductor layer 234 is formed to a thickness of 30 nm in an oxygen atmosphere, an argon atmosphere, or an atmosphere including argon and oxygen under the condition where a target for an oxide semiconductor (a target for an In—Ga—Zn—O-based oxide semiconductor (In₂O₃:Ga₂O₃:ZnO=1:1:2 [molar ratio])) is used, the distance between the substrate and the target is 170 mm, the substrate temperature is 400° C., the pressure is 0.4 Pa, and the direct current (DC) power is 0.5 kW.

Then, the substrate is transferred to the second heating chamber 122, and second heat treatment is performed. By the second heat treatment, impurities such as hydrogen, water, and a hydroxyl group in the oxide semiconductor layer 234 can be removed and the oxide semiconductor layer 234 in which the impurities are extremely reduced can be obtained. The second heat treatment is performed at a temperature higher than or equal to 250° C. and lower than or equal to 750° C., preferably higher than or equal to 400° C. and lower than or equal to 750° C., in an atmosphere of nitrogen, oxygen, a rare gas typified by argon, or a mixed gas of any of these.

After that, the substrate is only transferred through the fourth deposition chamber 114 and the third heating chamber 123 without being processed therein, and the substrate is carried into the unload chamber 102.

Through the above steps, the oxide semiconductor layer 234 which is formed over the oxide insulating layer 231 and has a reduced impurity concentration is obtained.

In the case where the oxide insulating layer 231 is not needed, the deposition treatment in the first deposition chamber 111 and the heat treatment in the first heating chamber 121 can be omitted.

Through the above steps, an oxide semiconductor layer having an extremely reduced impurity concentration can be formed. By forming an oxide semiconductor layer through such steps, the process can be further simplified, which is preferable.

Note that a glass substrate is used as the substrate 100 for description of the method for forming an oxide semiconductor layer in this embodiment. When the method is applied to a manufacturing process of a bottom-gate transistor, for example, a substrate provided with a gate electrode layer may be used as the substrate; thus, a substrate at a stage in the manufacturing process can be used.

In addition, the deposition apparatus described in this embodiment has a structure in which exposure to the air is thoroughly prevented, from the load chamber through each treatment chamber to the unload chamber, and the substrate can always be transferred under clean and reduced-pressure environment. Therefore, entry of an impurity into an interface of a film formed with this deposition apparatus can be suppressed, so that a film whose interfacial state is extremely favorable can be formed. By using such a film for a semiconductor device, for example, generation of a trap level at the interface can be suppressed and thus the semiconductor device can have high reliability.

As described above, with the deposition apparatus of one embodiment of the present invention, formation steps of an oxide semiconductor layer can be successively performed without exposure to the air even on a large-sized substrate such as a mother glass with the use of a series of apparatuses in which the impurity concentration is reduced. An oxide semiconductor layer formed with the deposition apparatus is a semiconductor layer having an extremely reduced impurity concentration. Such a semiconductor layer is used for a semiconductor device such as a transistor, whereby a semiconductor device having stable electric characteristics and high reliability can be realized.

This embodiment can be implemented in an appropriate combination with any of the other embodiments described in this specification.

### (Example of Method for Manufacturing Transistor)

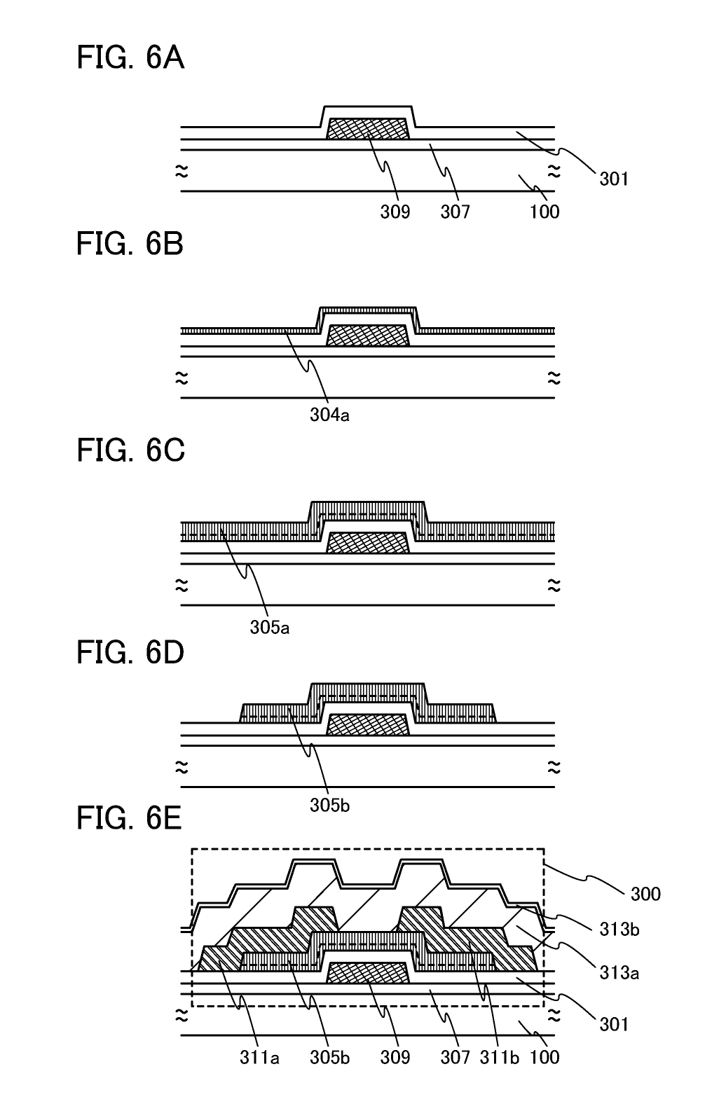

In this embodiment, an example of a method for manufacturing a bottom-gate transistor with the use of the above deposition apparatus will be described with reference to FIGS. 6A to 6E.

FIG. 6E is a cross-sectional view of a bottom-gate transistor 300. The bottom-gate transistor 300 includes, over the substrate 100 having an insulating surface, a base insulating layer 307, a gate electrode layer 309, a gate insulating layer 301, an oxide semiconductor layer 305b including a channel formation region, a source electrode layer 311a, a drain electrode layer 311b, and an oxide insulating layer 313a. The source electrode layer 311a and the drain electrode layer 311b are provided over the oxide semiconductor layer 305b. A region functioning as the channel formation region is part of a region of the oxide semiconductor layer 305b, which overlaps with the gate electrode layer 309 with the gate insulating layer 301 positioned therebetween.

A protective insulating layer 313b is provided to cover the oxide insulating layer 313a.

A process for manufacturing the bottom-gate transistor 300 over the substrate will be described below with reference to FIGS. 6A to 6E.

First, the base insulating layer 307 is formed over the substrate 100.

The base insulating layer 307 is formed by a PCVD method or a sputtering method to have a thickness greater than or equal to 50 nm and less than or equal to 600 nm with the use of one of a silicon oxide film, a gallium oxide film, an aluminum oxide film, a silicon nitride film, a silicon oxynitride film, an aluminum oxynitride film, and a silicon nitride oxide film or a stacked layer including any of these films. The base insulating layer 307 preferably includes oxygen at an amount which exceeds at least that in the stoichiometric composition ratio in (in a bulk of) the film. For example, in the case where a silicon oxide film is used, the composition formula is SiO_{2+α} (α>0).

In this embodiment, a 50-nm-thick silicon oxide film is formed as the base insulating layer 307 by a sputtering method.

In the case where a glass substrate including an impurity such as an alkali metal is used, a silicon nitride film, an aluminum nitride film, or the like may be formed as a nitride insulating layer between the base insulating layer 307 and the substrate 100 by a PCVD method or a sputtering method in order to prevent entry of an alkali metal. Since an alkali metal such as Li or Na is an impurity, it is preferable to reduce the content of such an alkali metal.

Next, a conductive film is formed over the base insulating layer 307 and then subjected to a photolithography step, so that the gate electrode layer 309 is formed.

The conductive film used for the gate electrode layer 309 can be formed by a sputtering method or the like to have a single-layer structure or a stacked-layer structure using any of metal materials such as molybdenum, titanium, tantalum, tungsten, aluminum, copper, neodymium, and scandium, or an alloy material including any of these materials as a main component.

In this embodiment, a tungsten film with a thickness of 150 nm is formed by a sputtering method as the conductive film used for the gate electrode layer.

Then, the substrate 100 over which the gate electrode layer 309 is formed is carried into the load chamber 101. In the load chamber, preheating may be performed on the substrate 100. When evacuation treatment is performed while preheating is performed, an impurity including hydrogen, preferably also an impurity including carbon or the like, which is adsorbed to the substrate, can be eliminated.

Next, the substrate 100 is carried into the first deposition chamber 111, and the gate insulating layer 301 is formed.

The gate insulating layer 301 is an oxide insulating layer which is formed by a plasma CVD method, a sputtering method, or the like to have a single-layer structure or a stacked-layer structure using any of silicon oxide, silicon oxynitride, silicon nitride oxide, aluminum oxide, gallium oxide, aluminum oxynitride, aluminum nitride oxide, and hafnium oxide, or a mixed material of any of these. The thickness of the gate insulating layer 301 is greater than or equal to 10 nm and less than or equal to 200 nm.

In this embodiment, a 100-nm-thick silicon oxide film is formed as the gate insulating layer 301 by a sputtering method.

FIG. 6A is a schematic cross-sectional view at this stage.

Next, the substrate 100 may be only transferred through the second deposition chamber 112 without being processed therein, and the substrate 100 may be transferred to the first heating chamber 121 to be subjected to first heat treatment.

By the first heat treatment, hydrogen and impurities including hydrogen such as water and a hydroxyl group, which are included in the gate insulating layer 301, can be effectively removed and thus diffusion of the above impurities into an oxide semiconductor layer formed later can be suppressed; therefore, the first heat treatment is preferably performed. Note that it is also possible for second heat treatment performed later to serve as the first heat treatment.

Next, the substrate is carried into the third deposition chamber 113, and a first oxide semiconductor film having a thickness greater than or equal to 1 nm and less than or equal to 10 nm is formed.

In this embodiment, the first oxide semiconductor film is formed to a thickness of 5 nm in an oxygen atmosphere, an argon atmosphere, or an atmosphere including argon and oxygen under the condition where a target for an oxide semiconductor (a target for an In—Ga—Zn—O-based oxide semiconductor (In₂O₃:Ga₂O₃:ZnO=1:1:2 [molar ratio])) is used, the distance between the substrate and the target is 170 mm, the substrate temperature is 250° C., the pressure is 0.4 Pa, and the direct current (DC) power is 0.5 kW.

Next, the substrate is transferred to the second heating chamber 122, and second heat treatment is performed. The second heat treatment is performed at a temperature higher than or equal to 400° C. and lower than or equal to 750° C. in an atmosphere of nitrogen or dry air. In addition, the heating time of the second heat treatment is longer than or equal to 1 minute and shorter than or equal to 24 hours. By the second heat treatment, the first oxide semiconductor film is crystallized, so that a crystalline oxide semiconductor layer 304a having c-axis alignment is formed (see FIG. 6B).

Then, the substrate is carried into the fourth deposition chamber 114, and a second oxide semiconductor film having a thickness greater than 10 nm is formed.

In this embodiment, the second oxide semiconductor film is formed to a thickness of 25 nm in an oxygen atmosphere, an argon atmosphere, or an atmosphere including argon and oxygen under the condition where a target for an oxide semiconductor (a target for an In—Ga—Zn—O-based oxide semiconductor (In₂O₃:Ga₂O₃:ZnO=1:1:2 [molar ratio])) is used, the distance between the substrate and the target is 170 mm, the substrate temperature is 400° C., the pressure is 0.4 Pa, and the direct current (DC) power is 0.5 kW.

Next, the substrate is carried into the third heating chamber 123, and third heat treatment is performed. The third heat treatment is performed at a temperature higher than or equal to 400° C. and lower than or equal to 750° C. in an atmosphere of nitrogen or dry air. In addition, the heating time of the third heat treatment is longer than or equal to 1 minute and shorter than or equal to 24 hours. By the third heat treatment, the second oxide semiconductor film is crystallized with the use of crystal in the oxide semiconductor layer 304a as a nucleus, so that an oxide semiconductor layer 305a in which the second oxide semiconductor film is combined with the oxide semiconductor layer 304a is formed (see FIG. 6C).

Note that a dashed line indicates an interface between the oxide semiconductor layer 304a and the second oxide semiconductor film; however, since these are combined to be the oxide semiconductor layer 305a by the third heat treatment, the interface is not distinct.

When the second heat treatment and the third heat treatment are performed at a temperature higher than 750° C., a crack (a crack extending in the thickness direction) is easily caused in the oxide semiconductor layer owing to shrink of the glass substrate. Thus, the temperature of heat treatment performed after formation of the first oxide semiconductor film, e.g., the temperatures of the second heat treatment and the third heat treatment, the substrate temperature in deposition by sputtering, or the like is set to be 750° C. or lower, preferably 450° C. or lower, whereby a highly reliable transistor can be manufactured over a large-sized glass substrate.

Then, the substrate 100 is carried into the unload chamber 102, and the substrate is carried out of the apparatus from the unload chamber 102.

Next, the oxide semiconductor layer 305a is processed, so that the oxide semiconductor layer 305b having an island shape is formed.

The oxide semiconductor layer can be processed by being etched after a mask having a desired shape is formed over the oxide semiconductor layer. The mask may be formed by a method such as photolithography. Alternatively, the mask may be formed by a method such as an ink jet method.

For the etching of the oxide semiconductor layer, either wet etching or dry etching may be employed. Needless to say, both of them may be employed in combination.

FIG. 6D is a schematic cross-sectional view at this point.

Next, a conductive film for forming a source electrode layer and a drain electrode layer (including a wiring formed in the same layer as the source electrode layer and the drain electrode layer) is formed over the oxide semiconductor layer 305b and processed, so that the source electrode layer 311a and the drain electrode layer 311b are formed.

The conductive film used for the source electrode layer 311a and the drain electrode layer 311b can be formed by a sputtering method or the like to have a single-layer structure or a stacked-layer structure using any of metal materials such as molybdenum, titanium, tantalum, tungsten, aluminum, copper, neodymium, and scandium, or an alloy material including any of the these materials as a main component.

Next, the oxide insulating layer 313a and the protective insulating layer 313b are formed to cover the oxide semiconductor layer 305b, the source electrode layer 311a, and the drain electrode layer 311b (see FIG. 6E). The oxide insulating layer 313a is preferably formed using an oxide insulating material, and after film formation, third heat treatment is preferably performed. By the third heat treatment, oxygen is supplied from the oxide insulating layer 313a to the oxide semiconductor layer 305b. The third heat treatment is performed at a temperature higher than or equal to 200° C. and lower than or equal to 400° C., preferably higher than or equal to 250° C. and lower than or equal to 320° C., in an inert atmosphere, an oxygen atmosphere, or a mixed atmosphere of oxygen and nitrogen. In addition, the heating time of the third heat treatment is longer than or equal to 1 minute and shorter than or equal to 24 hours.

In order to prevent entry of an alkali metal, a silicon nitride film is formed as the protective insulating layer 313b by a sputtering method. Since an alkali metal such as Li or Na is an impurity, the content of such an alkali metal is preferably reduced.

The concentration of the alkali metal in the oxide semiconductor layer is 2×10¹⁶ cm⁻³ or lower, preferably 1×10¹⁵ cm⁻³ or lower. Although a two-layer structure of the oxide insulating layer 313a and the protective insulating layer 313b is described as an example in this embodiment, a single-layer structure may be used.

Through the above steps, the bottom-gate transistor 300 is formed.

In the bottom-gate transistor 300 illustrated in FIG. 6E, the oxide semiconductor layer 305b is at least partly crystallized and has c-axis alignment. Thus, the highly reliable bottom-gate transistor 300 can be achieved.

In this embodiment, an oxide semiconductor layer formed with the deposition apparatus of one embodiment of the present invention is used for a bottom-gate transistor; however, the structure of the transistor is not limited to this and it is easy for those skilled in the art to think of application to an oxide semiconductor layer of a transistor having another bottom-gate structure or a top-gate structure.

As described above, with the deposition apparatus of one embodiment of the present invention, formation steps of an oxide semiconductor layer can be successively performed without exposure to the air even on a large-sized substrate such as a mother glass with the use of a series of apparatuses in which the impurity concentration is reduced. An oxide semiconductor layer formed with the deposition apparatus is a semiconductor layer having an extremely reduced impurity concentration. A transistor manufactured using such a semiconductor layer has stable electric characteristics and high reliability.

This embodiment can be implemented in an appropriate combination with any of the other embodiments described in this specification.

### (Oxide Semiconductor Film Having Alignment)

As described above, by using the deposition apparatus and deposition method described in this embodiment, an oxide semiconductor film having alignment can be obtained. When a transistor is manufactured using such an oxide semiconductor film, the transistor can have high reliability. One reason for high reliability of a transistor including a crystalline oxide semiconductor film will be described below.

A crystalline oxide semiconductor has higher orderliness of a bond between metal and oxygen (-M-O-M-, where O represents an oxygen atom and M represents a metal atom) than an amorphous oxide semiconductor. In other words, in the case where an oxide semiconductor has an amorphous structure, the coordination number may vary depending on the metal atom. In contrast, in the case of a crystalline oxide semiconductor, the coordination number is substantially uniform. Accordingly, microscopic oxygen vacancies can be reduced, and instability and charge transfer due to attachment or detachment of a hydrogen atom (including a hydrogen ion) or an alkali metal atom in a “space” described later can be reduced.

On the other hand, in the case of an amorphous structure, since the coordination number varies depending on the metal atom, the concentration of metal atoms or oxygen atoms may be microscopically uneven and there may be some portions where no atom exists (“space”). In such a “space”, for example, a hydrogen atom (including a hydrogen ion) or an alkali metal atom is trapped and, in some cases, bonded to oxygen. Further, it is possible for those atoms to move through such a “space”.

Such movement of an atom may cause variation in characteristics of an oxide semiconductor, and thus the existence of such an atom leads to a significant problem in reliability. In particular, such movement of an atom is caused by application of a high electric field or light energy; therefore, when an oxide semiconductor is used under such a condition, characteristics thereof are unstable. That is, the reliability of an amorphous oxide semiconductor is inferior to that of a crystalline oxide semiconductor.

Hereinafter, a difference in reliability will be described using actually obtained results on transistors (Sample 1 and Sample 2).

As a method for examining the reliability, an Id-Vg curve of a transistor is measured, which is obtained by measuring the current (Id) between a drain electrode and a source electrode of the transistor when the voltage (Vg) between a gate electrode and the source electrode of the transistor is changed with the transistor irradiated with light. In a transistor including an oxide semiconductor film, when a −BT test is performed, i.e., when a negative gate stress is applied with the transistor irradiated with light, degradation in which the threshold voltage of the transistor is changed is caused. This degradation is also referred to as negative-bias temperature stress photodegradation.

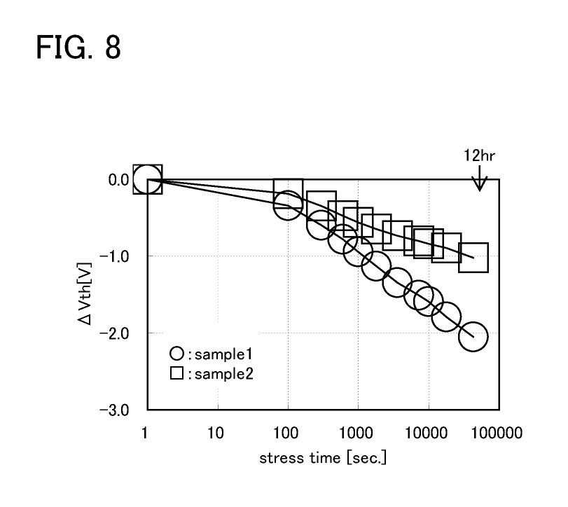

Negative-bias temperature stress photodegradation in Samples 1 and 2 is shown in FIG. 8.

In FIG. 8, the amount of change in Vₜₕ in Sample 2 is smaller than that in Sample 1.

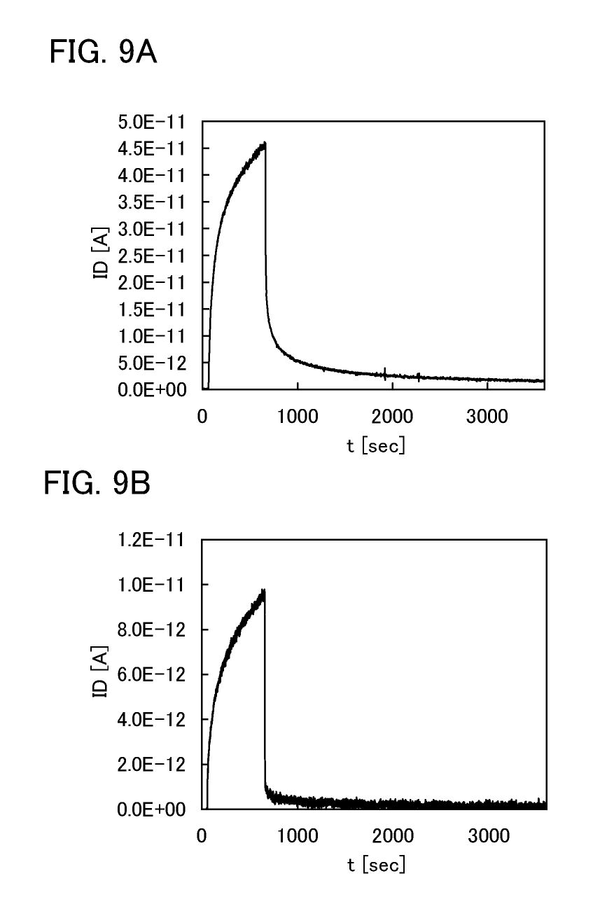

FIG. 9A is a graph of photoresponse characteristics (a graph of time dependence of photocurrent) which is made on the basis of results of measuring photoresponse characteristics of the transistor of Sample 1 (L/W=3 μm/50 μm) before and after it is irradiated with light (wave length: 400 nm, irradiation intensity: 3.5 mW/cm²) for 600 seconds. Note that the source-drain voltage (Vd) is 0.1 V.

FIG. 9B is a graph of photoresponse characteristics (a graph of time dependence of photocurrent) which is made on the basis of results of measuring photoresponse characteristics of the transistor of Sample 2 (L/W=3 μm/50 μm) before and after it is irradiated with light (wave length: 400 nm, irradiation intensity: 3.5 mW/cm²) for 600 seconds.

Further, measurement was performed on a transistor which was formed under the same manufacturing condition as Sample 2 and had a larger W width (L/W=30 μm/10000 μm) and a transistor which was formed under the same manufacturing condition as Sample 2, had the larger W width, and was supplied with higher Vd (Vd=15V), and fitting was performed on the measurement results. Two kinds of relaxation time (τ1 and τ2) are shown in Table 1.

TABLE 1

| | Imax[A] | τ₁[sec] | τ₂[sec] |
|---|---|---|---|
| Sample1: L/W = 3/50, Vd = 0.1 V | 4.60E−11 | 2.6 | 90 |
| Sample2: L/W = 3/50, Vd = 0.1 V | 9.20E−12 | 0.4 | 43 |
| L/W = 30/100000 μm, Vd = 0.1 V | 6.20E−11 | 0.3 | 39 |
| L/W = 30/100000 μm, Vd = 15 V | 9.20E−10 | 0.4 | 75 |

Note that the two kinds of relaxation time (τ1 and τ2) depend on the trap density. A method for calculating τ1 and τ2 is referred to as a photoresponse defect evaluation method.

It is found from Table 1 that each of the transistors formed under the manufacturing condition of Sample 2, in which negative-bias temperature stress photodegradation is small, has higher photoresponse characteristics than Sample 1. Accordingly, a relation that higher photoresponse characteristics are obtained as negative-bias temperature stress photodegradation is smaller can be found.

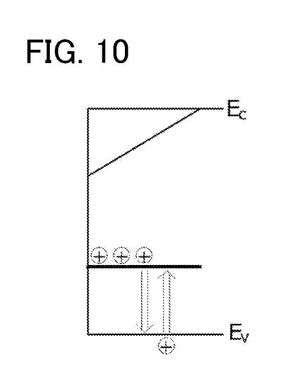

One reason for that will be described. If there exists a deep donor level and a hole is trapped by the donor level, the hole might become fixed charge by a negative bias applied to a gate in negative-bias temperature stress photodegradation and the relaxation time of a current value might be increased in photoresponse. A reason why a transistor including a crystalline oxide semiconductor film has small negative-bias temperature stress photodegradation and high photoresponse characteristics is thought to be attributed to low density of the above donor level that traps a hole. FIG. 10 is a schematic diagram of an assumed donor level.

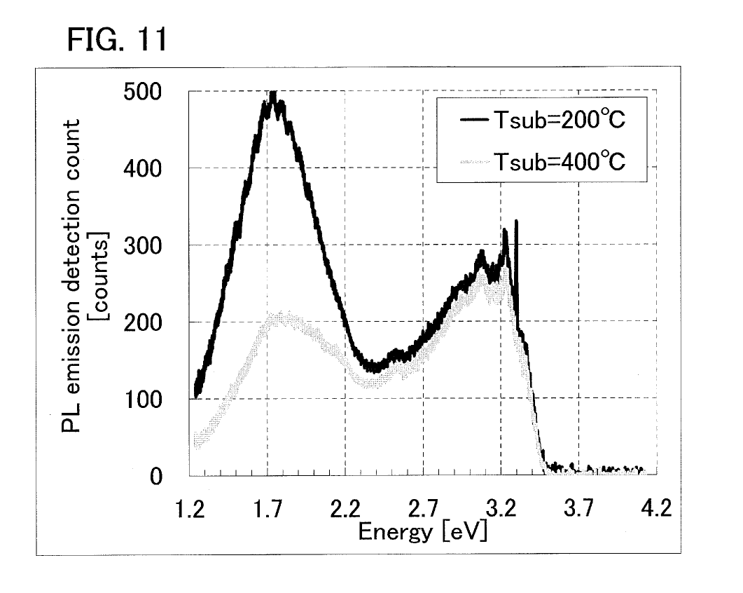

In order to examine changes in the depth and density of the donor level, measurement using low-temperature PL was performed. FIG. 11 shows measurement results in the case where the substrate temperature in formation of an oxide semiconductor film is 400° C. and in the case where the substrate temperature in formation of an oxide semiconductor film is 200° C.

According to FIG. 11, when the substrate temperature in formation of the oxide semiconductor film is 400° C., the peak intensity in the vicinity of about 1.8 eV is much lower than that in the case where the substrate temperature is 200° C. The measurement results indicate that the density of the donor level is significantly reduced while the depth thereof is not changed.

Oxide semiconductor films were formed under varied conditions of the substrate temperature, were compared to each other, and were each evaluated as a single film.

Sample A has a structure in which a 50-nm-thick oxide semiconductor film is formed over a quartz substrate (thickness: 0.5 mm). Note that the oxide semiconductor film is formed under the following condition: a target for an oxide semiconductor (a target for an In—Ga—Zn—O-based oxide semiconductor (In₂O₃:Ga₂O₃:ZnO=1:1:2 [molar ratio])) is used; the distance between the substrate and the target is 170 mm; the substrate temperature is 200° C.; the pressure is 0.4 Pa; the direct current (DC) power is 0.5 kW; and the atmosphere is a mixed atmosphere of argon (30 sccm) and oxygen (15 sccm).

The electron spin resonance (ESR) is measured at room temperature (300 K). With the use of a value of a magnetic field (H0) where a microwave (frequency: 9.5 GHz) is absorbed for an equation g=hv/βH₀, a parameter of a g-factor is obtained. Note that h and β represent the Planck constant and the Bohr magneton, respectively, and are both constants.

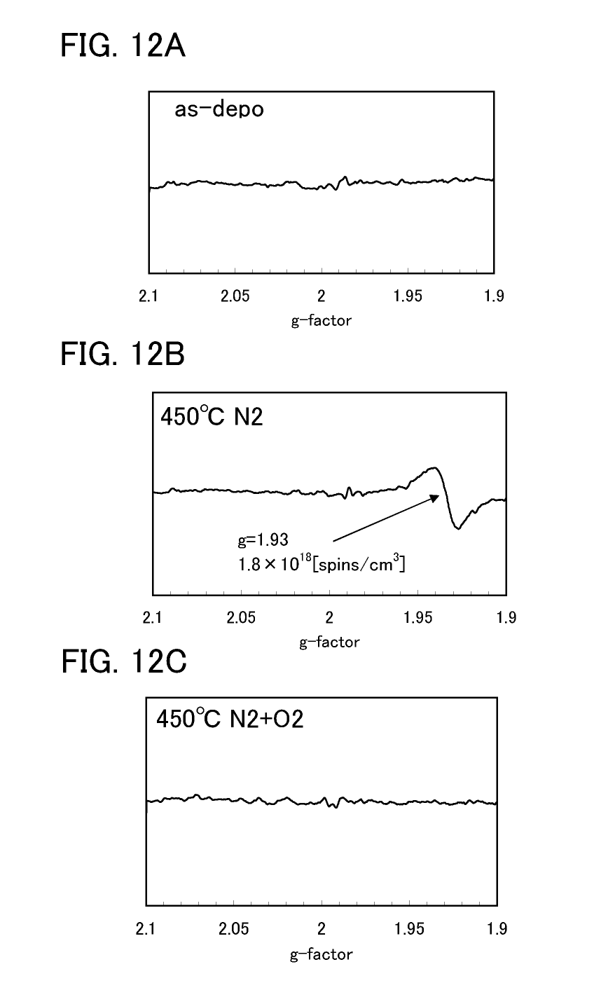

FIG. 12A is a graph showing the g-factor of Sample A.

Sample B is formed in such a manner that deposition is performed under the same condition as Sample A and then heating is performed at 450° C. for 1 hour in a nitrogen atmosphere. FIG. 12B is a graph showing the g-factor of Sample B.

Sample C is formed in such a manner that deposition is performed under the same condition as Sample A and then heating is performed at 450° C. for 1 hour in a mixed atmosphere of nitrogen and oxygen. FIG. 12C is a graph showing the g-factor of Sample C.

In the graph of the g-factor of Sample B, a signal of g=1.93 can be observed and the spin density is 1.8×10¹⁸ [spins/cm³]. On the other hand, the signal of g=1.93 cannot be observed in the result of ESR measurement of Sample C, and thus the signal of g=1.93 is attributed to a dangling bond of metal in the oxide semiconductor film.

In addition, Samples D, E, F, and G each have a structure in which a 100-nm-thick oxide semiconductor film is formed over a quartz substrate (thickness: 0.5 mm). Note that the oxide semiconductor film is formed under the following condition: a target for an oxide semiconductor (a target for an In—Ga—Zn—O-based oxide semiconductor (In₂O₃:Ga₂O₃:ZnO=1:1:2 [molar ratio])) is used; the distance between the substrate and the target is 170 mm; the pressure is 0.4 Pa; the direct current (DC) power is 0.5 kW; and the atmosphere is a mixed atmosphere of argon (30 sccm) and oxygen (15 sccm). Samples D, E, F, and G are formed at different substrate temperatures: room temperature for Sample D, 200° C. for Sample E, 300° C. for Sample F, and 400° C. for Sample G.

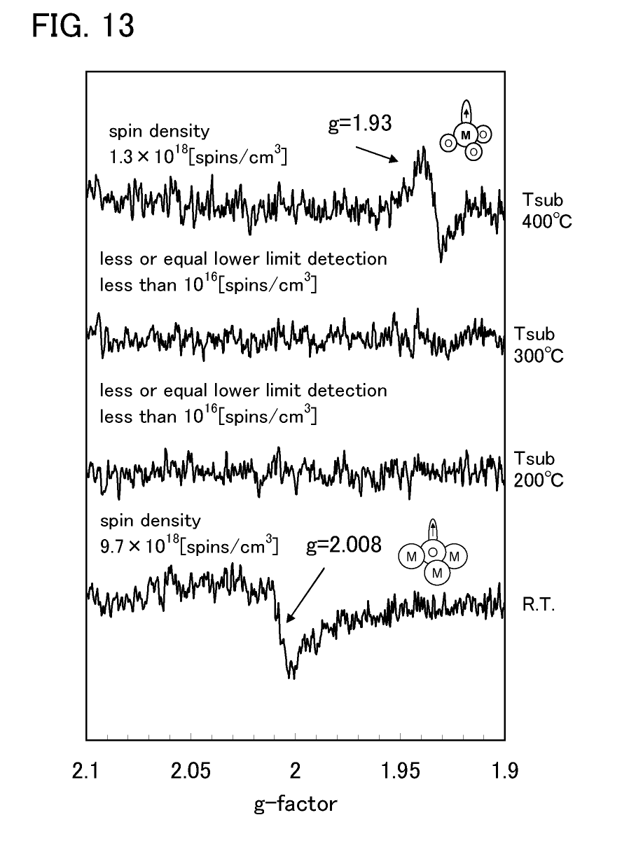

Graphs of the g-factor of Samples D, E, F, and G are shown in this order in FIG. 13.

In Sample G whose substrate temperature in deposition is 400° C., the signal of g=1.93 can be observed and the spin density is 1.3×10¹⁸ [spins/cm³]. The spin density is the same level as the spin density of the signal of g=1.93 obtained in Sample B.

From these results, it is confirmed that the anisotropy of the g-factor is increased when the substrate temperature in deposition is increased, which can be thought to be attributed to improvement in crystallinity. The results also indicate that a dangling bond that causes the signal g=1.93 depends on the film thickness and exists in a bulk of IGZO.

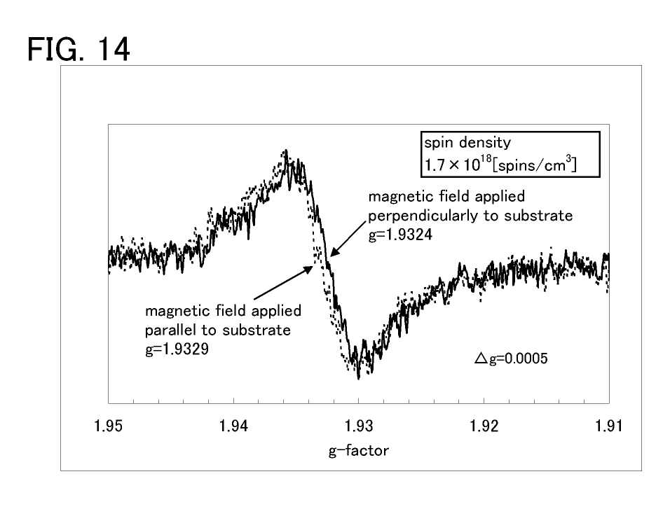

FIG. 14 is a graph of ESR measurement of Sample B and shows a difference (anisotropy) in the g-factor between the case where a magnetic field is applied perpendicularly to a substrate surface and the case where a magnetic field is applied in parallel to the substrate surface.

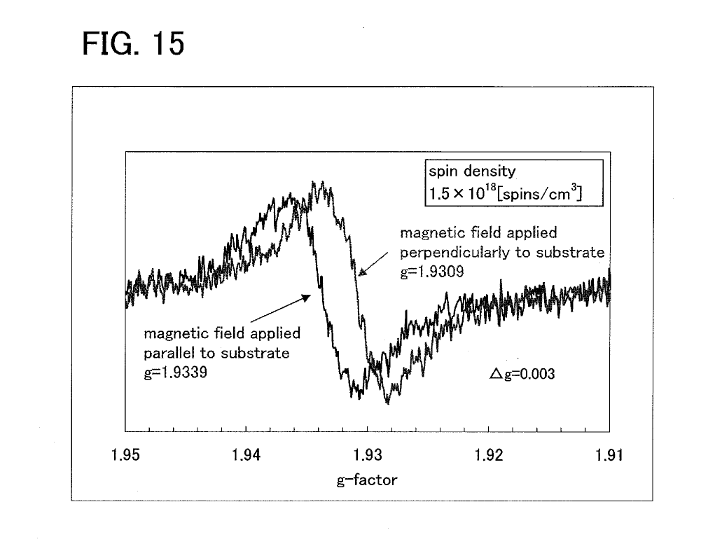

FIG. 15 is a graph of ESR measurement of Sample H which is formed in such a manner that deposition is performed under the same condition as Sample G and then heating is performed at 450° C. for 1 hour in a nitrogen atmosphere, and shows a difference (anisotropy) in the g-factor between the case where a magnetic field is applied perpendicularly to a substrate surface and the case where a magnetic field is applied in parallel to the substrate surface.

As a result of comparison between FIG. 14 and FIG. 15, it is found that the change Ag in the g-factor due to anisotropy is 0.001 or lower at a substrate temperature of 200° C. whereas the change Ag is increased to approximately 0.003 at a substrate temperature of 400° C. It is generally known that the anisotropy is increased as the crystallinity becomes higher (directions of orbits are more aligned). Thus, a conclusion is led that in a film formed at a substrate temperature of 400° C., the directions of dangling bonds of metal generated by heating at 450° C. for 1 hour in a nitrogen atmosphere are well aligned as compared to those in a film formed at a substrate temperature of 200° C.; that is, the former has higher crystallinity than the latter.

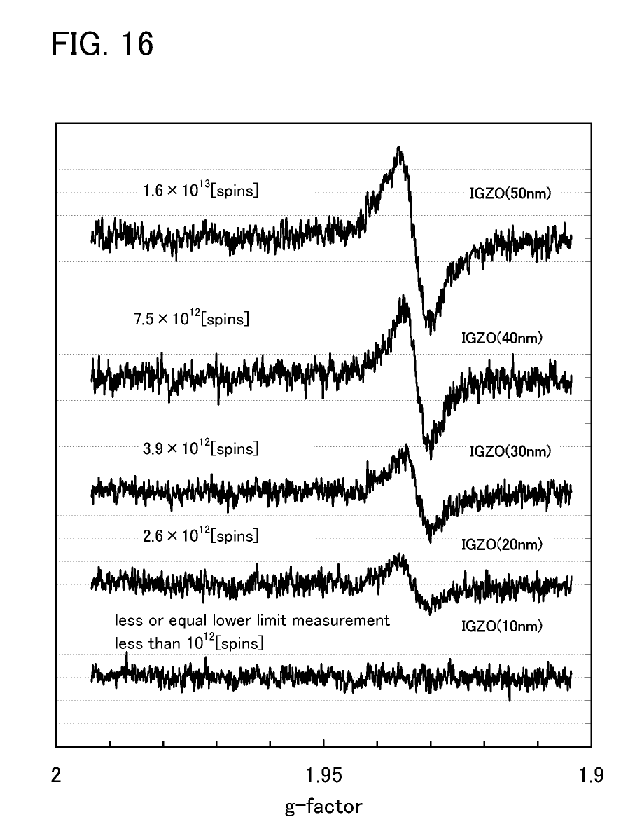

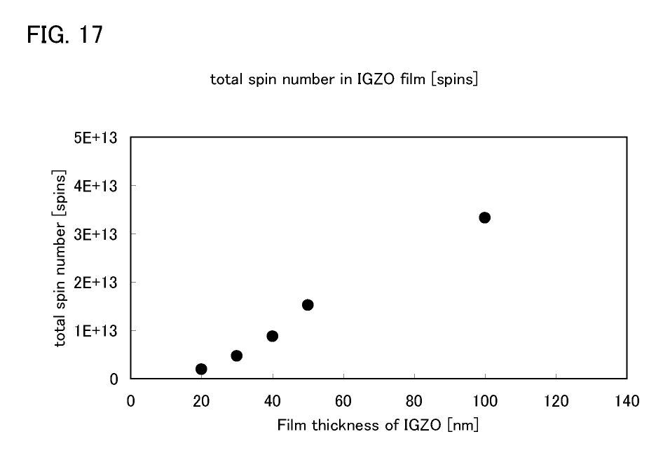

Further, ESR measurement was performed under varied conditions of the thickness of an oxide semiconductor film. Change in the intensity of the signal g=1.93 is shown in FIG. 16 and FIG. 17. From the results in FIG. 16 and FIG. 17, it is confirmed that the intensity of the signal g=1.93 is increased as the thickness of the oxide semiconductor film is increased. This indicates that a dangling bond that causes the signal g=1.93 exists not at an interface between the quartz substrate and the oxide semiconductor film or a surface of the oxide semiconductor film but in a bulk of the oxide semiconductor film.

It is found from these results that a dangling bond of metal has anisotropy and that the anisotropy is increased as the deposition temperature gets higher because higher crystallinity is obtained at higher deposition temperature. In addition, it is found that the dangling bond of metal exists not at the interface or surface but in the bulk.

This application is based on Japanese Patent Application serial no. 2010-204909 filed with the Japan Patent Office on Sep. 13, 2010, the entire contents of which are hereby incorporated by reference.

What is claimed is:

1. A deposition apparatus comprising:
a transfer mechanism for a substrate;
a first deposition chamber in which a first film comprising an oxide is formed; and
a first heating chamber in which a first heat treatment is performed,
wherein the first deposition chamber and the first heating chamber are sequentially provided along a path of the substrate transferred by the transfer mechanism,
wherein the substrate is held so that an angle formed by a deposition surface of the substrate and a vertical direction is in a range of greater than or equal to 1° and less than or equal to 30°, and
wherein without exposure to air, the first heat treatment is performed after the first film is formed over the substrate.

2. The deposition apparatus according to claim 1,
wherein the first film comprises an oxide semiconductor.

3. A deposition method comprising the steps of:
forming a first film comprising an oxide over a substrate in a first deposition chamber; and then
performing a first heat treatment in a first heating chamber without exposure to air,
wherein the substrate is processed while being held so that an angle formed by a deposition surface of the substrate and a vertical direction is in a range of greater than or equal to 1° and less than or equal to 30°.

4. The deposition method according to claim 3,
wherein the first film comprises an oxide semiconductor.

5. An apparatus for successive deposition comprising:
a transfer mechanism for a substrate;
a first deposition chamber in which a first film comprising an insulating film is formed;
a first heating chamber in which a first heat treatment is performed;
a second deposition chamber in which a second film comprising an oxide is formed; and
a second heating chamber in which a second heat treatment is performed,
wherein the first deposition chamber, the first heating chamber, the second deposition chamber, and the second heating chamber are sequentially provided along a path of the substrate transferred by the transfer mechanism,
wherein the substrate is held so that an angle formed by a deposition surface of the substrate and a vertical direction is in a range of greater than or equal to 1° and less than or equal to 30°, and
wherein without exposure to air, the first heat treatment is performed after formation of the first film, and then the second heat treatment is performed after formation of the second film.

6. The apparatus for successive deposition according to claim 5,
wherein the second film comprises an oxide semiconductor.

7. An apparatus for successive deposition comprising:
a transfer mechanism for a substrate;
a first deposition chamber in which a first film comprising an oxide including at least a first metal element and a second metal element is formed;
a first heating chamber in which a first heat treatment is performed;
a second deposition chamber in which a second film comprising an oxide is formed; and
a second heating chamber in which a second heat treatment is performed,
wherein the first deposition chamber, the first heating chamber, the second deposition chamber, and the second heating chamber are sequentially provided along a path of the substrate transferred by the transfer mechanism,
wherein the substrate is held so that an angle formed by a deposition surface of the substrate and a vertical direction is in a range of greater than or equal to 1° and less than or equal to 30°, and
wherein without exposure to air, the first heat treatment is performed after formation of the first film, and then the second heat treatment is performed after formation of the second film.

8. The apparatus for successive deposition according to claim 7,
wherein the second film comprises an oxide semiconductor.

9. The apparatus for successive deposition according to claim 7,
wherein the first metal element is zinc.

10. The apparatus for successive deposition according to claim 7,
wherein the second metal element is gallium.

11. A deposition method comprising the steps of:
forming a first film comprising an insulating film over a substrate in a first deposition chamber;
performing a first heat treatment in a first heating chamber;
forming a second film comprising an oxide in a second deposition chamber; and
performing a second heat treatment in a second heating chamber,
wherein the substrate is processed while being held so that an angle formed by a deposition surface of the substrate and a vertical direction is in a range of greater than or equal to 1° and less than or equal to 30°.

12. The deposition method according to claim 11,
wherein the second film comprises an oxide semiconductor.

13. A deposition method comprising the steps of:
forming a first film comprising an oxide including at least a first metal element and a second metal element over a substrate in a first deposition chamber;
performing a first heat treatment in a first heating chamber;
forming a second film comprising an oxide in a second deposition chamber; and
performing a second heat treatment in a second heating chamber,
wherein the substrate is processed while being held so that an angle formed by a deposition surface of the substrate and a vertical direction is in a range of greater than or equal to 1° and less than or equal to 30°.

14. The deposition method according to claim 13,
wherein the second film comprises an oxide semiconductor.

15. The deposition method according to claim 13,
wherein the first metal element is zinc.

16. The deposition method according to claim 13,
wherein the second metal element is gallium.

17. A deposition apparatus comprising:
a transfer mechanism for a substrate;
a first deposition chamber in which a first film is formed; and
a first heating chamber in which a first heat treatment is performed,
wherein the first deposition chamber and the first heating chamber are sequentially provided along a path of the substrate transferred by the transfer mechanism,
wherein the substrate is held so that an angle formed by a deposition surface of the substrate and a vertical direction is in a range of greater than or equal to 1° and less than or equal to 30°, and
wherein without exposure to air, the first heat treatment is performed and the first film is formed over the substrate.

18. The deposition apparatus according to claim 17,
wherein the first film comprises an oxide semiconductor.
